(19) United States
(12) Patent Application Publication
(10) Pub. No.: US 2009/0045061 A1
(43) Pub. Date: Feb. 19, 2009

(54) Nanotube Devices and Vertical Field Effect Transistors

(75) Inventors: Reginald C. Farrow, Somerset, NJ (US); Zafar Iqbal, Morristown, NJ (US); Amit Goyal, Harrison, NJ (US); Sheng Liu, Harrison, NJ (US)

Correspondence Address: MCCARTER & ENGLISH , LLP STAMFORD OFFICE, FINANCIAL CENTRE , SUITE 304A, 695 EAST MAIN STREET, STAMFORD, CT, 06901-2138, US

(73) Assignee: NEW JERSEY INSTITUTE OF TECHNOLOGY, Newark, NJ (US)

(21) Appl. No.: 12/143,132

(22) Filed: Jun. 20, 2008

Related U.S. Application Data
(60) Provisional application No. 60/945,170, filed on Jun. 20, 2007.

(51) Int. Cl. C25D 13/02

(52) U.S. Cl. 204/471; 977/742

(57) ABSTRACT

A method of depositing nanotubes in a region defined by an aperture is disclosed. The method provides advantageous control over the number of nanotubes to be deposited, as well as the pattern and spacing of nanotubes. Electrophoretic deposition, along with proper configuration of the aperture, allows at least one nanotube to be deposited in a target region with nanometer scale precision. Pre-sorting of nanotubes, e.g., according to their geometries or other properties, may be used in conjunction with embodiments of the invention to facilitate fabrication of devices with specific performance requirements. The method is useful for many applications where it is desirable to deposit more than one nanotube in a defined region. For example, vertical field effect transistor (VFET) designs may benefit from having more than one nanotube forming a channel to allow more current to flow through the device. By controlling the number of nanotubes to be deposited, one can ensure that the VFET output can be designed with sufficient current to meet the parameters of a logic circuit input.

### CROSS-REFERENCE TO RELATED APPLICATIONS

The present application is related to and claims priority benefit to a co-pending, commonly assigned provisional patent application entitled “NANOTUBE DEVICES,” which was filed on Jun. 20, 2007 and assigned Ser. No. 60/945,170. The entire contents of the foregoing provisional patent application are incorporated herein by reference.

### BACKGROUND

1. Technical Field

The present invention generally relates to a nanotube device and method of forming the device, and more particularly, to a method for controllably depositing one or more nanotubes in a defined region. The present invention further generally relates to a method of forming a nanotube vertical field effect transistor.

2. Background

There are many applications where a nanotube, e.g., a carbon nanotube (CNT), or an array of nanotubes, can be employed as a sensing or active device element in an electrical probe or electronic device. In these applications, electrical contact must be made with the nanotube, which requires accurate positioning of the nanotube with respect to various conductive links (i.e. interconnects) and other circuitry.

Aside from the need for precise alignment, properties of the nanotube also need to be controlled in order to provide device performance according to desired specifications. For example, many transistor applications for CNTs are best achieved with single wall carbon nanotubes (SWNT) rather than multi-wall carbon nanotubes (MWNT). Furthermore, as an active element of a transistor, a semiconducting SWNT, rather than a metallic SWNT, is required. For other applications such as interconnects and nanoprobes, however, a metallic CNT is preferred.

Existing fabrication methods for CNT devices do not fully address both needs for alignment and property control. In addition, in CNT electrical device fabrication, at least one interconnect level may be processed before CNT deposition. The most common metallization schemes, e.g., with aluminum and copper interconnects, often impose thermal budget constraints for subsequent processing steps. Chemical vapor deposition (CVD) methods, which are typically used for depositing CNTs, are not compatible with aluminum or copper interconnects because of the relatively high temperatures involved.

### SUMMARY

In the fabrication of CNT devices, there is often a need to provide a vertically oriented CNT inside an aperture. In transistor fabrication processes, depending on the specific stage or levels, the aperture is also referred to as a via.

Embodiments of the present invention provide a method of depositing nanotubes in a region defined by an aperture, with control over the number of nanotubes to be deposited, as well as the pattern and spacing of nanotubes. Specifically, electrophoretic deposition, along with proper configuration of the aperture, allows at least one nanotube to be deposited in a target region with nanometer scale precision. Pre-sorting of nanotubes, e.g., according to their geometries or other properties, may be used in conjunction with embodiments of the invention to facilitate fabrication of devices with specific performance requirements.

Embodiments of the present invention also provide a method of controlling the number of nanotubes to be deposited and their spacings in a given region. Such a method is useful for many applications where it is desirable to deposit more than one nanotube in a defined region. For example, certain vertical field effect transistor (VFET) designs may benefit from having more than one nanotube forming a channel to allow more current to flow through the device. Thus, by controlling the number of nanotubes to be deposited, one can ensure that the VFET output can be designed with sufficient current to meet the parameters of a logic circuit input.

Additional advantageous features, functions and implementations of the present disclosure will be apparent from the description which follows, particularly when read in conjunction with the accompanying figures.

### BRIEF DESCRIPTION OF THE DRAWINGS

The teachings of the present invention can be readily understood by considering the following detailed description in conjunction with the accompanying drawings, in which:

FIG. 1 is schematic cross-sectional view of a nanotube-based structure that can be fabricated using embodiments of the present invention;

FIGS. 2A-D are schematic diagrams illustrating an experimental setup and a process sequence for depositing a carbon nanotube according to one embodiment of the present invention;

FIGS. 3A-C are schematic illustrations of the electric field distributions around an aperture with a diameter of 100 nm and a depth of 50 nm;

FIGS. 4A-B are schematic illustrations of electric field distributions around an aperture with a diameter of 500 nm and a depth of 50 nm;

FIG. 5A is a schematic illustration of a nanotube sensor array;

FIG. 5B is a cross-sectional view of the nanotube sensor array of FIG. 5A;

FIGS. 6A-J are illustrations of cross-sectional views of structures during various stages of a sensor fabrication sequence;

FIG. 7 is a schematic illustration of an experimental arrangement of using a nanotube sensor as an intracellular probe;

FIG. 8 is a schematic illustration of a nanotube-based transistor that can be fabricated using embodiments of the present invention; and

FIGS. 9A-B are schematic illustrations of a configuration of an aperture suitable for implementing embodiments of the present invention.

FIG. 10 is a schematic illustration of a nanotube-based transistor that can be fabricated using embodiments of the present invention;

FIGS. 11A-B are schematic illustrations of a configuration of an aperture suitable for implementing embodiments of the present invention; and

FIGS. 12A-I are schematic cross-sectional views of structure during various stages of a carbon nanotube field effect transistor fabrication sequence.

FIG. 13 is a schematic microscopic view of CNT intracellular probe inserted into a cell.

FIG. 14 is a schematic view of an experimental arrangement for electrically probing a cell with one or more CNTs.

FIG. 15 is a schematic of a process sequence for fabricating CNT probes: a) quartz wafer substrate, b) photoresist deposition, c) pattern photoresist and deposit interconnect metal, d) remove photoresist, e) deposit photoresist, f) pattern photoresist, g) deposit contact metal (Au), h) remove resist, i) deposit insulating layer (silicon nitride), j) deposit photoresist, k) expose and develop photoresist and reactive ion etch silicon (RIE) nitride, l) remove photoresist, m) deposit CNT or SWNT using electrophoresis, n) deposit passivation layer (polymer or silicon nitride), o) deposit poly-Si, p) polish to desired probe length and RIE or chemically etch to uncover tips of CNT probes, q) poly-Si, r) deposit photoresist, s) expose and develop photoresist and RIE to open windows to contacts, and t) remove resist.

FIG. 16 is a schematic of the electrostatic potential of a cell membrane.

FIG. 17 is a plot of conductance vs. strain measured from a SWNT suspended over a trench and bent by an AFM tip and the conductance vs. bending angle is plotted in the inset.

FIG. 18 is a plot of force vs. deflection angle for an SWNT cantilever.

FIG. 19a is an SEM image of oriented single wall carbon nanotube “forests” electrochemically functionalized by enzyme as discussed in text above (alignment is perpendicular to the plane of the image displayed) and FIG. 19b is a plot of cyclic voltammogram during functionalization of single wall nanotubes with enzyme.

To facilitate understanding, identical reference numerals have been used, where possible, to designate identical elements that are common to the figures.

### DETAILED DESCRIPTION

The present disclosure is described herein with reference to the accompanying figures, wherein exemplary embodiments are schematically depicted or otherwise described.

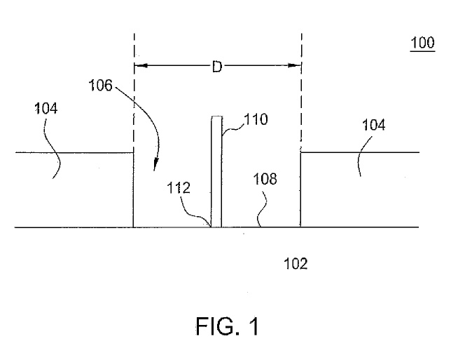

FIG. 1A is a schematic cross-sectional view of a nanotube structure 100 that can be fabricated using embodiments of the present invention. The structure 100 includes a substrate 102, over which an insulating material layer 104 has been deposited. The insulating layer 104 has been patterned to form an aperture 106, which exposes a top surface 108 of the substrate 102. A single CNT 110 is deposited inside the aperture 106 so that one end 112 of the CNT 110 contacts the top surface of the substrate 102. The substrate 102 is a conducting material such as a metal or a conducting film (deposited over an insulating material) that allows a bias voltage to be applied for electrophoretic deposition of the nanotube 110.

Embodiments of the present invention allow the CNT 110 to be deposited inside the aperture 106, to the exclusion of other CNTs. The aperture 106, which has to be sufficiently large to accommodate the CNT 110, may be patterned using different lithographic processes. Thus, in one embodiment, the aperture 106 may have a diameter (D) ranging from about the lower limit (e.g., resolution) of the lithography process to about 100 nm. For example, existing lithography at 193 nm readily provides a resolution limit of about 90 nm. In one embodiment, the substrate 102 has a lateral dimension (e.g., extending across the aperture) sufficiently large to meet level-to-level overlay constraints with respect to the aperture 106. As will be shown below, the CNT 110 can be deposited proximate the center of the aperture 106, e.g., with a lateral alignment precision of a few nanometers. Furthermore, the CNT 110 may be pre-selected to have a preferred physical property including multiwall CNT versus single wall CNT and or conducting CNT versus semiconducting CNT.

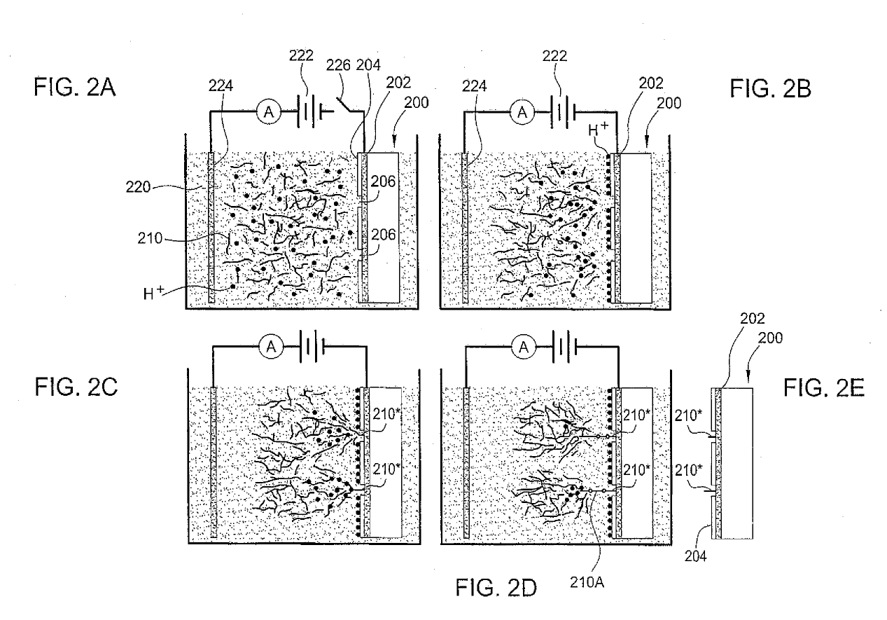

FIGS. 2A-D illustrate schematically an experimental setup for electrophoresis and a sequence for depositing a CNT on a substrate according to one embodiment of the present invention. Electrophoretic deposition (EPD) is driven by the motion of charged particles, dispersed in a suitable solvent, towards an electrode under the influence of an electric field. Particles less than about 30 μm size can be used in suspensions with low solid loading and low viscosity. In general, whether nanotubes are deposited in the form of bundles or individual tubes depends on the nature of the suspension and the relative mobilities of each, which depends on their shapes and the associated resistance to diffuse towards the contact surface inside the apertures or vias.

FIG. 2A shows a substrate structure 200 with a conductive layer 202. An insulating layer 204 is provided over the conductive layer 202, and one or more apertures 206 are patterned in the insulating layer 204. The substrate structure 200 is immersed in a liquid bath 220, e.g., at room temperature, containing an electrolyte and a suspension of CNTs 210 in a suitable solvent.

Successful EPD requires preparation of a stable dispersion. In general, an electrostatically stabilized dispersion can be obtained with particles of high ζ-potential, while keeping the ionic conductivity of the suspensions low. SWNTs have shown high ζ-potential values at low pH values. It is also known that the presence of charging salts can play an important role in improving adhesion of the nanotubes to substrates and increasing the deposition rates.

In one embodiment, 10 mg of purified SWNTs are suspended in 30 ml of distilled water, and 10⁻⁴ moles of magnesium nitrate hexahydrate [Mg(NO₃)26H₂0] is added to the suspension and sonicated for about 2-3 hrs. In general, it is preferable that the nanotubes in the liquid bath 220 be pre-sorted for the type of nanotubes according to application needs. For example, while semiconducting SWNTs are used as active elements in transistors, either semiconducting or metallic nanotubes may be used for probes or other devices. A few drops of non-ionic Triton-X surfactant are added to improve the suspension with a final pH of solution at about 4.

Aside from hydrogen ions (H⁺), shown as circles in FIG. 2A, the liquid bath 220 also contains magnesium ions, Mg²⁺, which tend to adsorb or attach to the CNTs. An electrode 224, e.g., a platinum electrode, is immersed in the liquid bath 220 and connected to a positive terminal of a DC voltage source 222. The conducting layer 202 is connected to a switch 226.

In FIG. 2A, when the switch 226 is open and there is no current flow inside the liquid bath 220 (current flow may be measured using an ammeter A), the CNTs are randomly distributed in the suspension and any deposition on the substrate will be random.

In FIG. 2B, the switch 226 is closed, thus connecting the conductive layer 202 to a negative terminal of the DC source 222. With a DC potential, e.g., in a range of about 5V-25V, applied across the platinum electrode 224 and the conductive layer 202, charged particles or species in the fluid will move towards either the cathode or the anode. For example, H⁺ ions and positively charged CNTs will move towards the substrate structure 200, which is the cathode in this case.

Since H⁺ ions have higher mobility than other positively charged species, including the CNTs, H⁺ ions will arrive at the substrate structure 200 faster than other charged species, and thus, preferentially accumulate on the surface of the insulating layer 204, as shown in FIG. 2B. The positively charged surfaces of the insulating layer 204 result in an electric field being produced around each aperture 206.

Positively-charged CNTs arriving near the substrate structure 200 are directed by the electric field towards the center of each aperture 206, as shown in FIG. 2C. Details regarding this “focusing” effect will be presented in later discussions. In one embodiment, the apertures 206 and electric field distribution are configured so that only one CNT (shown as CNT 210*) is deposited inside each aperture 206, even though the diameter (or lateral dimension) of the aperture 206 is large enough to physically accommodate additional CNTs. The CNT 210* is disposed inside each aperture 206 in a “longitudinal” manner, i.e., the length of the CNT 210* is along the same direction as the depth of the aperture 206, with one end of the CNT contacting the conductive layer 202.

FIG. 2D shows that the unattached end of CNT 210* tends to align or point towards the platinum electrode, and further, serves as a focal point for additional CNTs. Thus, a second CNT 210A becomes attached to the free end of CNT 210*, e.g., in a lengthwise manner, with additional CNTs attaching to each other end-to-end. The substrate structure 200 is then removed from the bath 220, washed in distilled and de-ionized water, and dried with an inert gas. After drying, only the CNTs 210* that are attached to the conductive layer 202 remain, and the resulting structure, such as one illustrated in FIG. 2E, is ready for further processing.

Since different devices often require different properties of the nanotubes for proper operation and/or optimum performance, it may be advantageous to provide a pre-sorting of the nanotubes prior to electrophoretic deposition. For example, nanotubes may be sorted according to their properties such as semiconducting versus metallic, single-walled versus multi-walled, or they may be sorted according to geometries or dimensions such as lengths, diameters, and so on.

Since different types of nanotubes have different mobilities, e.g., longer or multiwalled nanotubes will generally have lower mobility compared to shorter or single-walled nanotubes, electrophoresis may also be used for sorting purposes. Such sorting can be done prior to the electrophoretic deposition so that the nanotubes in the bath have a relatively uniform distribution in terms of properties and/or geometries. Alternatively, if the nanotubes in the electrophoresis bath have a relatively wide distribution in terms of geometries or other properties, a certain degree of sorting may also be achieved “in situ” during deposition by virtue of the different mobilities of the nanotubes.

The degree of focusing that directs the nanotubes towards the aperture is affected by the magnitude and shape of the electric field distribution, along with the configuration of the aperture. To provide control over the number of deposited nanotubes as well as their positioning, a finite element model is used to investigate the electric field distribution as a function of various input parameters. Parameters or factors that are relevant for controlling nanotube deposition include the aperture configuration, nanotube properties, characteristics of the insulating layer and substrate, bias potential, dielectric properties of the solution, among others. The aperture configuration may generally include the shape, dimensions (e.g., width, length, depth, ratios of dimensions), sidewall profile, and so on. The nanotube properties may generally include the dimensions (e.g., length, diameter), single-walled or multi-walled, semiconducting or metallic.

The electric field around the aperture results from a combination of the potential applied to the metal layer on the substrate structure and charges that accumulate on the surface of the insulating layer. The positive charge accumulation on the dielectric layer covering the cathode creates an electric field that opposes the field arising from the bias applied between the anode and cathode. Once the two electric fields become equal and opposite, positive charges will no longer be attracted to the surface of the insulating layer. This “saturation charge density”, σ, which determines the strength of the nanoscopic lens from the resulting electric field distribution, can be calculated from:

σ=∈₀∈ᵣE Eq. (1)

where E is the magnitude of the electric field between the anode and cathode, ∈₀ is the permittivity of free space, and ∈ᵣ is the relative permittivity of the liquid.

As an example, for E=10³ V/m, ∈₀=8.85×10⁻¹² Farad/meter and the liquid is water ∈ᵣ=80, the surface charge density σ is equal to 7.1×10⁻⁷ Coulomb/meter².

Once the specific aperture geometry is selected and the surface charge density is calculated, the electric field in the region near the apertures and the motion of positively charged particles can be calculated using finite element analysis techniques that are well known. Thus, with proper configuration and design, one can obtain an electric field distribution to produce a desired focusing or lens effect to direct the nanotube deposition.

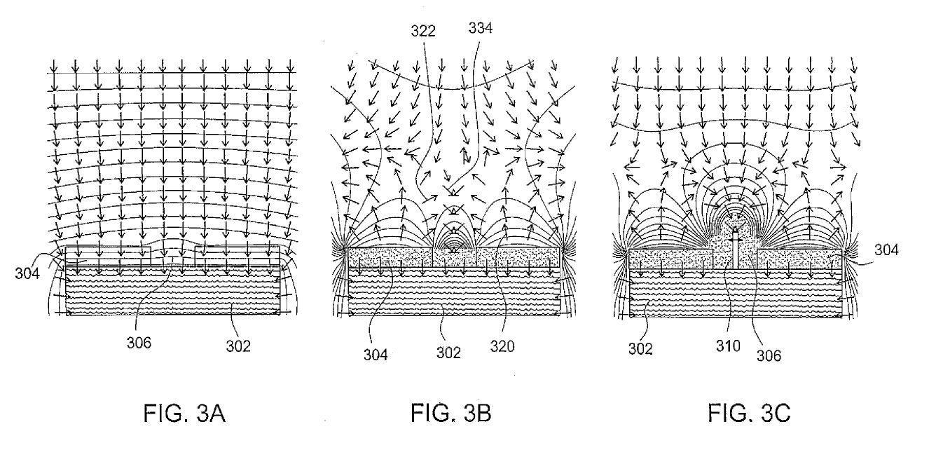

FIGS. 3A-C show the results of electric field distributions around an aperture 306 having a diameter of 100 nm and a depth of 50 nm. In this example, a negative 10V bias is applied to the conductive layer 302. FIG. 3A shows the electric field distribution before H⁺ ions are accumulated on the insulating surface. The electric field distribution is relatively uniform, with field lines mostly perpendicular to the surfaces of the insulating layer 304. As shown in the figure, the field line directions are indicated by arrows pointing towards a region of negative potential. Only slight deviations of the field lines are seen at or close to the aperture 306.

FIG. 3B shows the modified electric field distribution after the surface of the insulating layer 304 is saturated with H⁺ ions. The arrows 320 above the insulating layer 304 show that positively charged species will be repelled away from the surface, while arrows 322 on either side of the aperture 306 show that the field lines are directed inwards, i.e., towards an area above the aperture 306. Near the center of the aperture 306, the field lines are directed downwards, i.e., towards the interior of the aperture 306, as indicated by arrows 334. Thus, positively charged species such as CNTs are directed towards the aperture 306.

After sufficient charges have accumulated to reach the charge saturation point, the electrostatic lens effect will direct all charged particles towards the center of the aperture 306. The equipotential lines for this geometry favor the focusing of mobile charged nanotubes towards the center of the aperture 306. In this case, the diameter of the aperture 306 is 100 nm and the depth is 50 nm. In this example, since the electric field distribution around the aperture 306 is substantially symmetric with respect to a central longitudinal axis of the aperture, the CNT 310 is also substantially centered inside the aperture 306. Thus, one end of the CNT 310 is attached to a region of the conductive layer 302 defined by the aperture 306 (i.e., the exposed region at the bottom of the aperture), e.g., within a few nanometers of the center of the defined region.

FIG. 3C shows the electric field distribution after one CNT 310 has been deposited inside the aperture 306. Since the CNT is conductive and is in electrical contact with the conductive layer 302, the electric field distribution is modified by the deposited CNT 310. Furthermore, if the aperture 306 is sufficiently small, as it is in this case, the electric field lines tend to concentrate towards the free end of CNT 310, instead of directing towards the interior of the aperture 306. Thus, the free end of CNT 310 becomes a focal point for further deposition of nanotubes, instead of being deposited at the bottom of the aperture 306.

In general, for a fixed potential difference between the reference electrode and the metal contact at the bottom of the aperture, the strength of the focusing effect is inversely proportional to the diameter of the aperture for a fixed aperture depth.

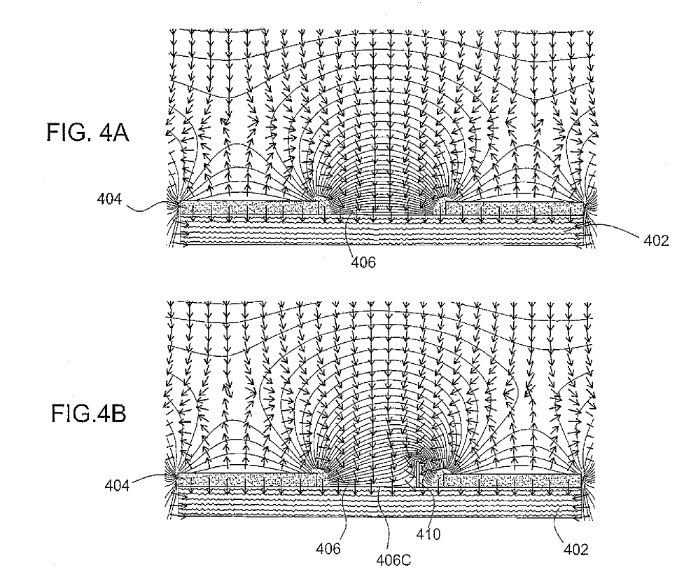

FIG. 4A-B show different results obtained for an aperture 406 having a diameter of 500 nm and a depth of 50 nm, with a negative 10V bias applied to a conductive layer 402. FIG. 4A shows the electric field lines around aperture 406, with H⁺ ions accumulated on the surface of insulating layer 404, and FIG. 4B shows the electric field lines modified by a CNT 410 inside the aperture 406. In this case, the CNT 410 is positioned with a lateral offset from the center 406C of the aperture 406, which may arise, for example, from a random direction of approach in the bath, followed by the electric field directing the nanotube to its location of deposition. As suggested by the field lines in the figure, more than one CNT may be deposited inside the aperture 406.

In this case, the electric field distribution will not provide a preferential direction to guide the nanotubes towards the center region of the aperture 406. The final location of the nanotube will depend on the initial position of the nanotube before the bias is applied. For a large aperture, e.g., diameter or lateral dimension of greater than about 100 nm, the unattached end of the first deposited nanotube may still be the focal point for further nanotube deposition. However, when the lateral dimension of the aperture is sufficiently large, the electric field will also direct other nanotubes to other locations on the exposed surface of the conductive layer 402.

Although results suggest that an aperture diameter of about 100 nm provide a transition or reference point below which deposition is restricted to a single nanotube, while apertures larger than about 100 nm tend to favor deposition of more than one nanotubes, it is understood that this reference point may vary with specific combinations of nanotubes and/or structural configurations.

Aside from the aperture diameter (or lateral dimension), other parameters, e.g., shape, aspect ratio (defined as depth or height of aperture divided by lateral dimension), among others, may also be used for the purpose of controlling deposition of nanotubes, for example, by providing different configurations according to the nanotube properties and/or geometries.

Results of another finite element analysis also show that, for nanotubes with a 10 nm diameter and a length of 100 nm, and an aperture formed in silicon nitride with a diameter of 100 nm and a depth (or height) of larger than 18 nm, only one nanotube will be deposited inside the aperture. This suggests that an aperture with an aspect ratio of at least 0.18 or greater may be used to restrict the number of deposited nanotubes to only one. For a nanotube with a smaller diameter, a larger aspect ratio may be required in order to restrict the deposition to only one nanotube. Similar analysis can be used to simulate probable locations of deposited nanotubes for other aperture configurations and nanotube properties. While a two dimensional analysis is suitable for situations in which a plane of symmetry is available, a three dimensional analysis can generally be used for other situations. Thus, finite element analysis can be used for nanoscopic lens design as a guide to providing nanotube deposition with additional levels of control.

Many different nanotube-based devices may be fabricated using the method of the present invention. While the method can generally be applied to the deposition of nanotubes within apertures of different dimensions, it is particularly well-suited for situations in which it is desirable to control the number of nanotubes to be deposited or the lateral positioning or alignment of the nanotube. Examples of nanotube-based devices that can benefit from this method include vertical CNT transistors, chemical sensors or biosensors, among others.

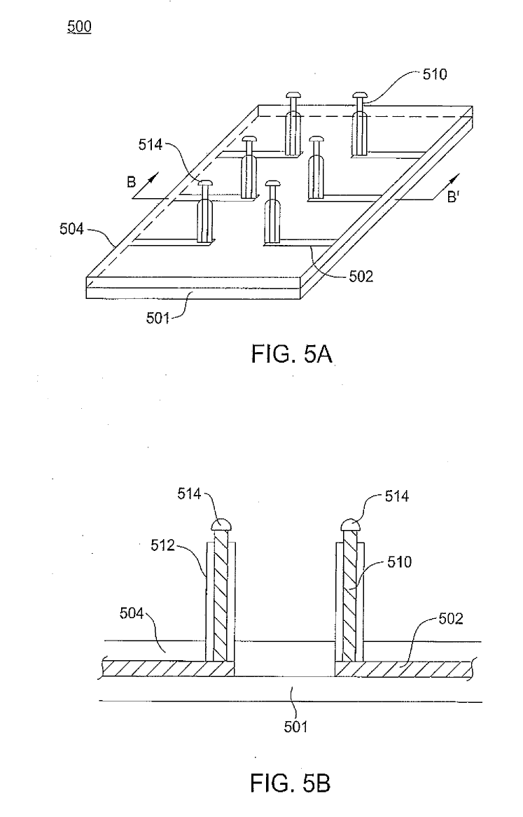

FIG. 5A is a schematic illustration of a nanotube-based sensor array device 500 according to one embodiment of the present invention, and FIG. 5B is a cross-sectional view along a vertical plane containing line BB′. Device 500 generally includes one or more nanotubes 510 that are deposited over a substrate 501. A conductive material 502, e.g., a metal, is formed at selected regions of the substrate 501 to provide conductive paths to the nanotubes 510. Nanotubes 510 can be deposited onto the conductive material 502 using electrophoresis as previously described, e.g., by forming apertures in an insulating layer 504 provided over the conductive material 502, and applying a bias voltage to the conductive material 502. A sheath 512 is also formed around each nanotube 510 to provide passivation and insulation for the nanotube 510. By insulating the sidewalls of the nanotubes 510 and leaving only the tips exposed, potential background noise may be reduced, thus increasing the electrical sensitivity of the sensor. The interconnects to the nanotubes 510 are used for measuring changes in the CNT electrical characteristics.

A device similar to that shown in FIGS. 5A-B may be used for investigating intracellular activities in biological cells. Specifically, a CNT is a good candidate for such a probe because its small diameter (e.g., compared to cell membrane thickness) can minimize distortions to the cell that is being investigated with the probe.

Depending on the specific sensor applications, different functional molecules 514 are provided to the other end of the nanotube 510. In general, SWNTs are preferred for sensor applications, although there may be situations in which MWNTs may also be used.

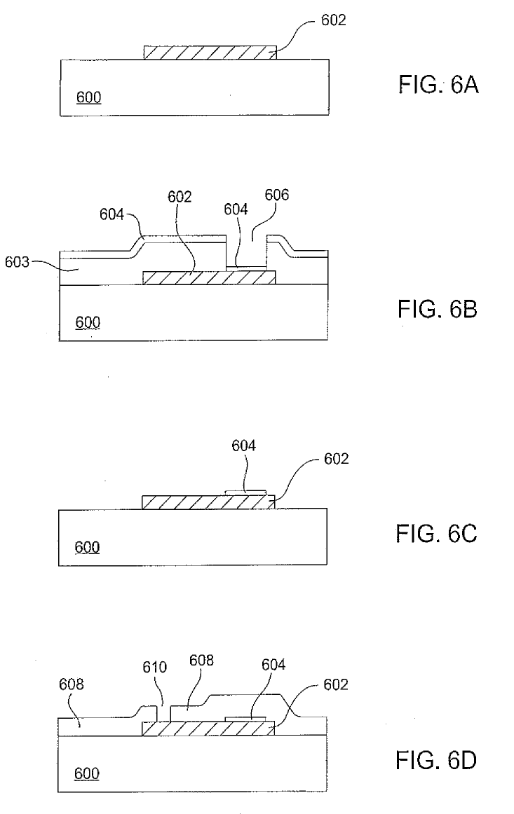

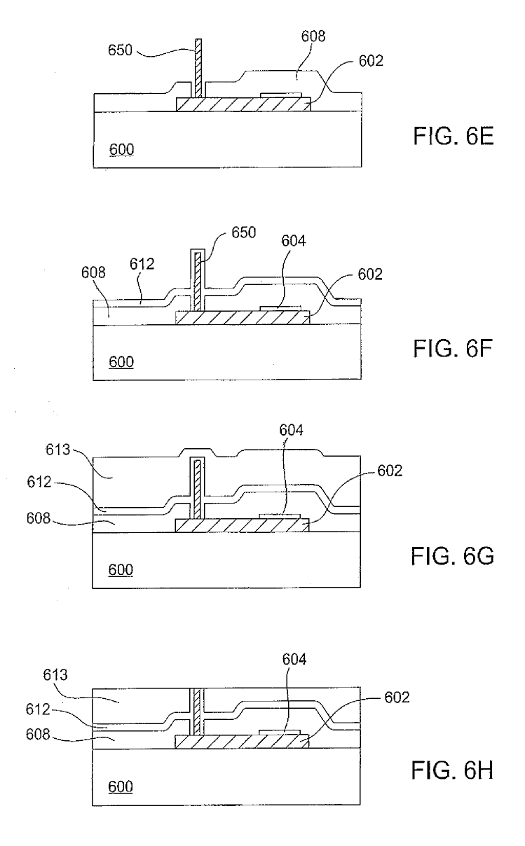

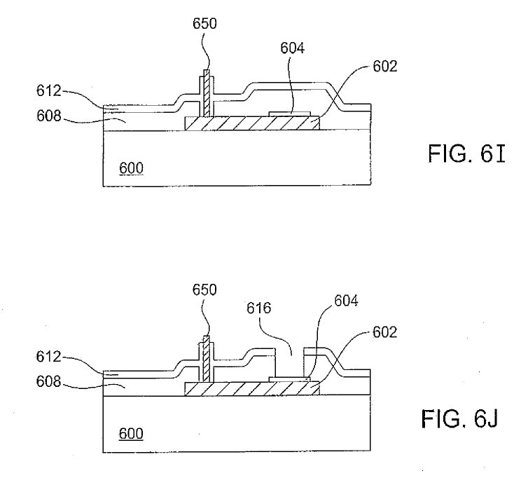

FIGS. 6A-J are schematic cross-sectional views of a sensor device structure during various stages of a process sequence suitable for forming a device array such as that shown in FIG. 5A. FIG. 6A shows a conductive portion 602 formed on a substrate 600. For a biosensor, quartz may be used as the substrate material, which will facilitate the viewing of a biological sample with an optical microscope in transmission mode. In one embodiment, quartz wafers of 100 mm diameter and 350 μm thickness may be used, and they can be cleaned and prepared prior to device fabrication using methods known to one skilled in the art. In general, however, any suitable substrate will suffice, including silicon. If the starting substrate is silicon, or other conducting material, then an insulating layer will first have to be deposited prior to the metal interconnects.

The conductive portion 602, e.g., an interconnect metal, can be deposited and patterned using photolithography and resist liftoff techniques known to one skilled in the art. The interconnect metal needs to be suitable for maintaining electrical contact and adhesion with CNTs, and may include, but not limited to, cobalt (Co), nickel (Ni), or iron (Fe).

To facilitate adhesion between the metal interconnect to the quartz substrate, an adhesion layer (not shown) may also be formed prior to the formation of the conductive portion 602. In one embodiment, cobalt (Co) is used as a metal interconnect, and a 20 nm thick chromium (Cr) adhesion layer is used to promote adhesion of cobalt to the quartz surface. The Cr layer may be evaporated at a rate of about 2 Ångstroms per second (Å/s), and a 120 nm thick Co layer can then be evaporated at a rate of about 1 Å/s. A thickness of about 20 nm and 120 nm may be used for the Cr and Co layers, respectively. The cobalt metal interconnect can also serve as the cathode during electrophoretic deposition of the nanotube

In the embodiment where CNTs are deposited using electrophoresis, the conductive portion 602 is configured to be electrically connected to contact pads (not shown) provided at the edge or periphery of the substrate 602. In one embodiment, each conductive portion 602 upon which a CNT will be deposited is provided as part of a continuous conductive layer formed over the substrate 600, in order to simplify the electrical connection paths. This facilitates electrical grounding of the metal during electron-beam lithography (if e-beam is used during fabrication) and provides a single connection point for electrophoretic deposition of CNTs. In one example, electrical connections between different devices are made in the kerf (area between each device), which allows the connections to be broken by a dicing saw when the substrate is cut to facilitate assembling the devices. Alternative configurations may also be used for providing the electrical connections needed during fabrication, and a variety of conventional lithographic and etching processes may be adapted for this purpose.

For each individual sensor device, a metal contact is needed to provide electrical connections to external circuits, for example, by soldering or wire bonding. In one embodiment, gold (Au) is used as the metal contact material. The metal contact can be formed using photolithography and resist liftoff techniques. FIG. 6B shows a structure during the metal contact formation stage, in which a photoresist layer 603 has been patterned to form an aperture 608 extending to an underlying region of the conductive portion 602. A conductive layer 604 is deposited over the patterned resist 603 and the exposed region of the conductive portion 602. When the resist layer 603 is removed from the structure of FIG. 6B, only the conductive layer inside the aperture 606 remains, resulting in a structure shown in FIG. 6C.

FIG. 6D shows an insulating layer 608 deposited over the substrate 600 and the conductive portion 602 and subsequently patterned to form an aperture 610 (also referred to as vias or windows). In one embodiment, silicon nitride (SiNx) is used as the insulating layer 608. The thickness of the insulating layer 608 is selected to provide an appropriate aspect ratio for electrostatic lens implementation after patterning. For example, a 50 nm thick SiNx film is suitable for forming apertures with a lateral dimension, e.g., diameter, of about 100 nm. For example, a 50 nm thick low stress SiNx film may be deposited at low temperatures by plasma enhanced chemical vapor deposition (PECVD) using Plasma Therm 790 standard equipment at a temperature of about 350° C. In the context of a sensor device, the SiNx layer serves two functions. Aside from providing an insulation layer for forming the apertures during device fabrication, the SiNx layer, in the completed sensor, also provides an insulating barrier between the conducting interconnect metal and the cell culture solutions in which measurements will be performed.

Using a suitable lithography process, aperture 610 having a lateral dimension of about 100 nm or less can be formed in the insulating layer 608. The aperture 610 is sufficiently large to accommodate a nanotube to be deposited onto substrate 602. In one embodiment, the aperture 610 has a diameter ranging from about the lower limit (e.g., resolution) of the lithography process to about 100 nm. In one embodiment, optical lithography using 193 nm source illumination may be used to pattern the aperture in photoresist, providing a resolution of about 90 nm. Alternatively, these apertures may also be fabricated using electron-beam lithography or a focused ion beam milling technique. Apertures with dimensions of less than about 100 nm are suitable for providing the electrostatic lens effect during electrophoretic deposition of nanotubes. The lithography technique of the interconnect metal and vias will limit the separation between the nanotube devices.

The structure of FIG. 6D can then be immersed in an electrolytic bath for electrophoretic deposition of nanotubes, using a similar setup as previously discussed in connection with FIG. 2. In one embodiment, a patterned structure with a cobalt metal layer on a quartz substrate is used as the negative electrode, and a platinum wire is used as the positive electrode. DC bias voltages in the range of about 5V-25V may be used.

FIG. 6E shows a structure after deposition of a nanotube 650 inside the aperture 610. Prior to electrophoretic deposition, the nanotubes may be presorted for metallic SWNTs and filtered to limit bundles of SWNTs. The length of the CNTs or SWNTs may, for example, be less than about 1 micron (μm), and will typically be determined by the application needs. In the case of a biosensor such as an intracellular probe, the length may depend on requirements for mechanical stability and penetration distance into the target cell.

After the nanotube 650 is deposited in the aperture 610, its vertical orientation may be affected by the rinse process or by charging effects. The nanotubes can be re-aligned to the vertical direction by applying an electrical potential between the metal level on which it was deposited and a metal plate above the wafer substrate. This may be done, for example, in a reactor prior to the subsequent deposition process in the fabrication sequence. Plasma processing systems typically have a metal plate above the wafer that is part of the electrical circuit for generating the plasma. By establishing a DC or AC electric field between this metal plate (or another electrode) and the metal level that the nanotube is deposited on, the nanotube can be re-aligned to a desired orientation prior to subsequent processing.

After nanotube deposition, a conformal film 612 of an insulating material having a thickness range of about 2-5 nm may be formed to encapsulate and passivate (or insulate) the nanotube 650. Suitable materials for this encapsulation film include SiNx or suitable polymers, e.g., polytetrafluoroethylene.

Since the sorting of nanotubes before or during electrophoretic deposition usually does not provide sufficiently precise control of the lengths of the nanotubes, additional trimming may be needed in order to provide a nanotube with a certain length specification. This can be achieved by the process steps illustrated in FIGS. 6G-H, showing a polysilicon layer 613 formed (e.g., grown or deposited) over the encapsulation film 612 (FIG. 6G). The polysilicon layer 615 can then be polished back, e.g., using chemical mechanical polishing (CMP), until the desired nanotube length is achieved, as shown in FIG. 6H.

A portion of the encapsulation film 612 around the tip of the deposited nanotube 650 can then be removed by a brief reactive ion etching (RIE) or chemical etch to uncover the tip of the nanotube 650. The length of nanotube 650 that is uncovered will depend on the etch rate and the time duration of the etch. RIE etches for SiNx are standard processes for fabrication of complementary metal oxide semiconductor (CMOS) integrated circuits, and etch rates are well known and incorporated into commercial SiNx etching apparatus.

The poly-Si layer 613 will then be removed to leave free standing encapsulated nanotube 650, as shown in FIG. 6I. FIG. 6J shows the structure after an aperture 616 is formed in the encapsulation film 612 and insulating layer 608 to expose the metal contact 606. The aperture 616 can be formed with standard photolithography and dry etching process that are known to one skilled in the art.

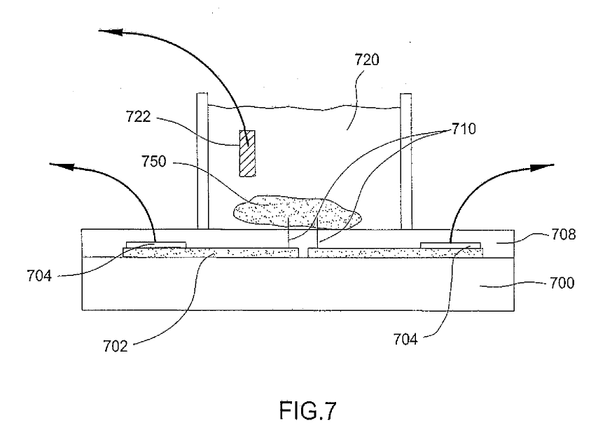

FIG. 7 is a schematic illustration of an experimental arrangement of using such a nanotube sensor as an intracellular probe. FIG. 7 shows two CNT probes 710, each connected to respective interconnect metal 702 formed over substrate 700. The CNT probes 710 are inserted into a cell 750 in a liquid bath 720 for electrical probing. A bath electrode 722 and the contact pads 704 (provided inside an aperture formed in insulating layer 708) are each connected to suitable electronics (not shown) to monitor the electrical characteristics indicative of intracellular activities.

The above embodiments and discussions illustrate the capability to controllably deposit a single nanotube with nanoscale lateral precision near a center of a region defined by an aperture. The method is particularly attractive from an implementation or processing viewpoint, because the ability to achieve such controlled deposition within a relatively large region significantly relaxes the requirement for lithographic techniques. As such, the fabrication can readily be performed using optical lithography, without resorting to more complicated lithographic tools (such as e-beam or focused ion beam) to form sufficiently small apertures to define the target deposition region.

Embodiments of the present invention also provide a method of controlling the number of nanotubes to be deposited and their spacings in a given region. Such a method is useful for many applications where it is desirable to deposit more than one nanotube in a defined region. For example, certain vertical field effect transistor (VFET) designs may benefit from having more than one nanotube forming a channel to allow more current to flow through the device. Thus, by controlling the number of nanotubes to be deposited, one can ensure that the VFET output can be designed with sufficient current to meet the parameters of a logic circuit input.

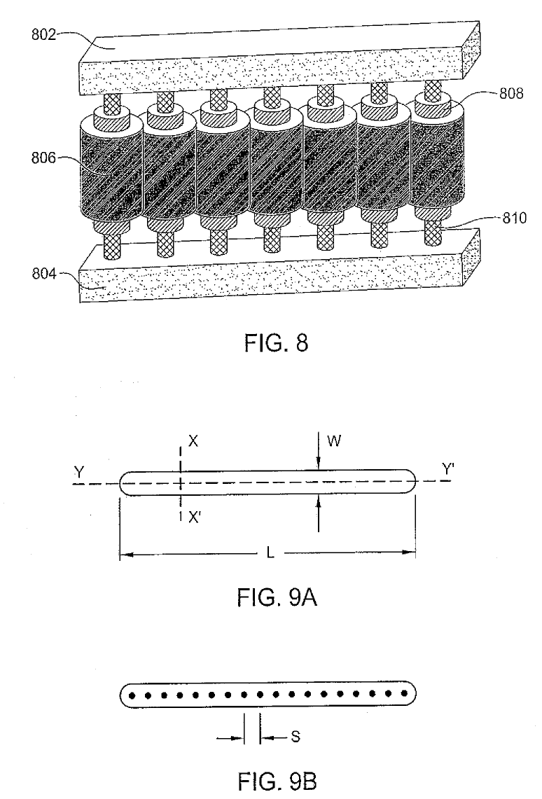

One constraint in the design of the VFET is that the lateral size of the device should be as small as possible to maximize the number of VFETs per unit area. One possibility is to fabricate closely spaced vias and connect each source 802, drain 804, and gate 806 in parallel, as shown in FIG. 8 (with CNT 810 serving as the channel of the device and separated from the gate 806 by gate dielectric 808). This concept was suggested by Hoenlein et al., Materials Science and Engineering C, 23, p. 663-669 (2003); and DE 0010036897 C1, (2000). However, the difficulty with fabricating closely spaced vias for positioning nanotubes is that the number of nanotubes per unit area is solely determined by the minimum diameter of the vias and the separation between vias. This imposes a stringent requirement on lithography and etch processing and, for VFET devices with reasonable maximum current per unit length (1500 microampere per micrometer), sub-20 nm diameter vias will be required.

Embodiments of the present invention will allow a device concept such as that shown in FIG. 8 to be fabricated without imposing stringent requirements on lithography. Specifically, an aperture can be configured to control the number of nanotubes, as well as their spacing or positioning, within the apertured region using electrophoretic deposition.

FIGS. 9A-B are schematic illustrations of a top view of an aperture configuration suitable for controlling nanotube deposition. As shown in FIG. 9A, the aperture has an elongated geometry such as a slot, which is characterized by a width (W), also referred to as a lateral or transverse dimension (along a direction indicated by line X-X′), and a length (L), also referred to as a longitudinal dimension (along a direction indicated by line Y-Y′), with L being larger than W. In this example, the width W is designed to be sufficiently narrow so as to allow only one nanotube to be deposited along the transverse direction. Thus, all deposited nanotubes will be deposited in a line pattern, i.e., lined up adjacent to each other, along the longitudinal direction.

Furthermore, the number of nanotubes deposited within the slot can be controlled by the length of the slot. Once a first nanotube is deposited in the slot the electric field distribution around the slot will be modified. The new field distribution can be calculated using finite element analysis. The closest separation between adjacent nanotubes can also be calculated by using finite element analysis to predict the trajectory of randomly approaching charged particles that are successively deposited in the slot.

Using this analysis for nanotubes having a length of 100 nm, it has been estimated that the closest separation between nanotubes with 1 nm diameter is about 15 nm. For nanotubes with a diameter of 10 nm and a length of 100 nm, the closest separation for adjacent nanotubes is about 20 nm. The same method can be used to calculate the closest separation of nanotubes with any geometry. An alternative method can be used to calculate the electric field in the vicinity of two closely spaced nanotubes and reduce the spacing until the calculated electric field has a distribution that would exclude deposition of a third nanotube in between the two that are already deposited.

Once the closest separation (s) between nanotubes is known, the number of nanotubes, N, deposited in the slot is given by: N=MOD(L/s). The function MOD( ) truncates the resulting number L/s to an integer. The shape at the ends of the slot may also modify this result, depending on the degree of rounding. The calculation is most accurate if there is no rounding. With the presence of rounding, an additional degree of focusing may reduce the number of deposited nanotubes, and this can be determined using three dimensional finite element analysis for the exact geometry.

As shown above, embodiments of the present invention provide a method for controllable depositing nanotubes using electrophoresis in a defined region. The deposition region may be defined by an aperture, which can be configured to control the number of nanotubes that can be deposited in the region, as well as the spacings of deposited nanotubes. By properly configuring the aperture, e.g., providing a sufficiently small aperture size such as less than about 100 nm, one can also control the deposition such that only a single nanotube is deposited in the region, with lateral alignment precision of a few nanometers.

Embodiments of the invention provide a room temperature process that is readily scalable and compatible with conventional fabrication processes and materials, and allow improved control over the properties of nanotubes being used in device fabrication.

Although some examples have been discussed in the context of the deposition of carbon nanotubes, it is understood that the method can generally be adapted for deposition of other nanotubes. Furthermore, embodiments of the invention can generally be applied to depositing single-walled, multi-walled, semiconducting or metallic nanotubes for fabrication of different devices.

The above embodiments and discussions illustrate the capability to controllably deposit a single nanotube with nanoscale lateral precision near a center of a region defined by an aperture. The method is particularly attractive from an implementation or processing viewpoint, because the ability to achieve such controlled deposition within a relatively large region significantly relaxes the requirement for lithographic techniques. As such, the fabrication can readily be performed using optical lithography, without resorting to more complicated lithographic tools (such as e-beam or focused ion beam) to form sufficiently small apertures to define the target deposition region.

Embodiments of the present invention also provide a method of controlling the number of nanotubes to be deposited and their spacings in a given region. Such a method is useful for many applications where it is desirable to deposit more than one nanotube in a defined region. For example, certain vertical field effect transistor (VFET) designs may benefit from having more than one nanotube forming a channel to allow more current to flow through the device. Thus, by controlling the number of nanotubes to be deposited, one can ensure that the VFET output can be designed with sufficient current to meet the parameters of a logic circuit input.

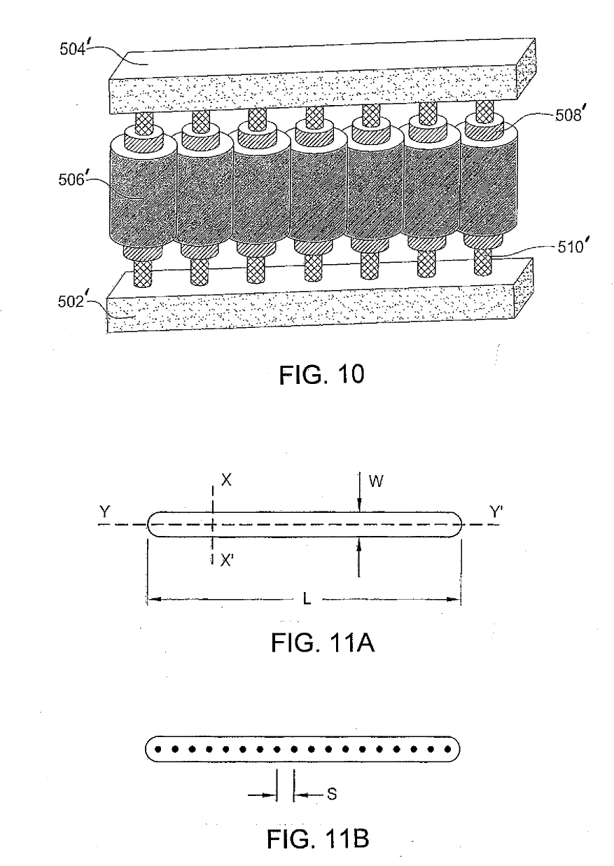

One constraint in the design of the VFET is that the lateral size of the device should be as small as possible to maximize the number of VFETs per unit area. One possibility is to fabricate closely spaced vias and connect each source 502′, drain 504′, and gate 506′ in parallel, as shown in FIG. 10 (with CNT 510′ serving as the channel of the device and separated from the gate 506′ by gate dielectric 508′). This concept was suggested by Hoenlein et al., Materials Science and Engineering C, 23, p. 663-669 (2003); and DE 0010036897 C1, (2000). However, the difficulty with fabricating closely spaced vias for positioning nanotubes is that the number of nanotubes per unit area is solely determined by the minimum diameter of the vias and the separation between vias. This imposes a stringent requirement on lithography and etch processing and, for VFET devices with reasonable maximum current per unit length (1500 microampere per micrometer), sub-20 nm diameter vias will be required.

Embodiments of the present invention will allow a device concept such as that shown in FIG. 10 to be fabricated without imposing stringent requirements on lithography. Specifically, an aperture can be configured to control the number of nanotubes, as well as their spacing or positioning, within the apertured region using electrophoretic deposition.

FIGS. 11A-B are schematic illustrations of a top view of an aperture configuration suitable for controlling nanotube deposition. As shown in FIG. 11A, the aperture has an elongated geometry such as a slot, which is characterized by a width (W), also referred to as a lateral or transverse dimension (along a direction indicated by line X-X′), and a length (L), also referred to as a longitudinal dimension (along a direction indicated by line Y-Y′), with L being larger than W. In this example, the width W is designed to be sufficiently narrow so as to allow only one nanotube to be deposited along the transverse direction. Thus, all deposited nanotubes will be deposited in a line pattern, i.e., lined up adjacent to each other, along the longitudinal direction.

Furthermore, the number of nanotubes deposited within the slot can be controlled by the length of the slot. Once a first nanotube is deposited in the slot, the electric field distribution around the slot will be modified. The new field distribution can be calculated using finite element analysis. The closest separation between adjacent nanotubes can also be calculated by using finite element analysis to predict the trajectory of randomly approaching charged particles that are successively deposited in the slot.

Using this analysis for nanotubes having a length of 100 nm, it has been estimated that the closest separation between nanotubes with 1 nm diameter is about 15 nm. For nanotubes with a diameter of 10 nm and a length of 100 nm, the closest separation for adjacent nanotubes is about 20 nm. The same method can be used to calculate the closest separation of nanotubes with any geometry. An alternative method can be used to calculate the electric field in the vicinity of two closely spaced nanotubes and reduce the spacing until the calculated electric field has a distribution that would exclude deposition of a third nanotube in between the two that are already deposited.

Once the closest separation (s) between nanotubes is known, the number of nanotubes, N, deposited in the slot is given by: N=MOD(L/s). The function MOD( ) truncates the resulting number L/s to an integer. The shape at the ends of the slot may also modify this result, depending on the degree of rounding. The calculation is most accurate if there is no rounding. With the presence of rounding, an additional degree of focusing may reduce the number of deposited nanotubes, and this can be determined using three dimensional finite element analysis for the exact geometry.

Embodiments described above can be used for fabricating different carbon nanotube (CNT) devices, e.g., a CNT field effect transistor (CNT-FET). Since the materials and processes for forming a CNT-FET are compatible with those typically used in complementary metal oxide semiconductors (CMOS), such a transistor can readily be integrated with CMOS processing to provide a three dimensional semiconductor structure.

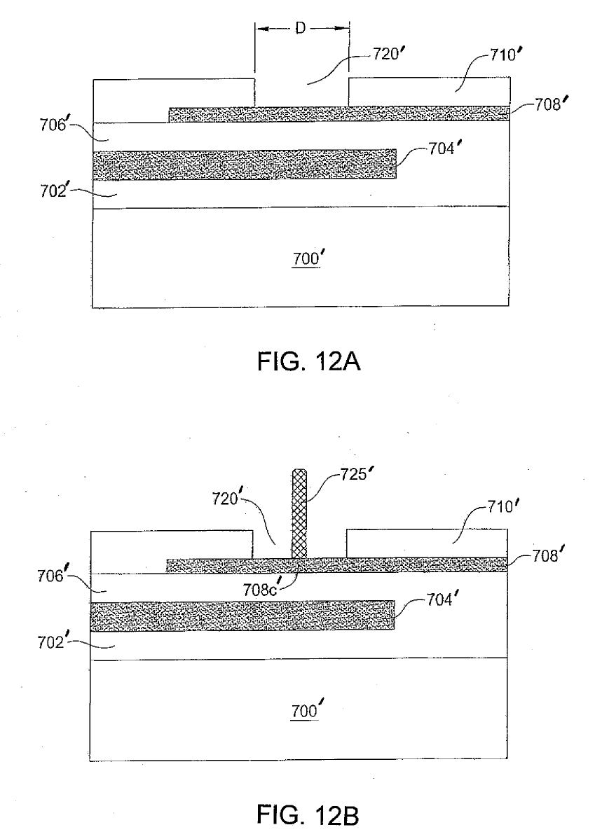

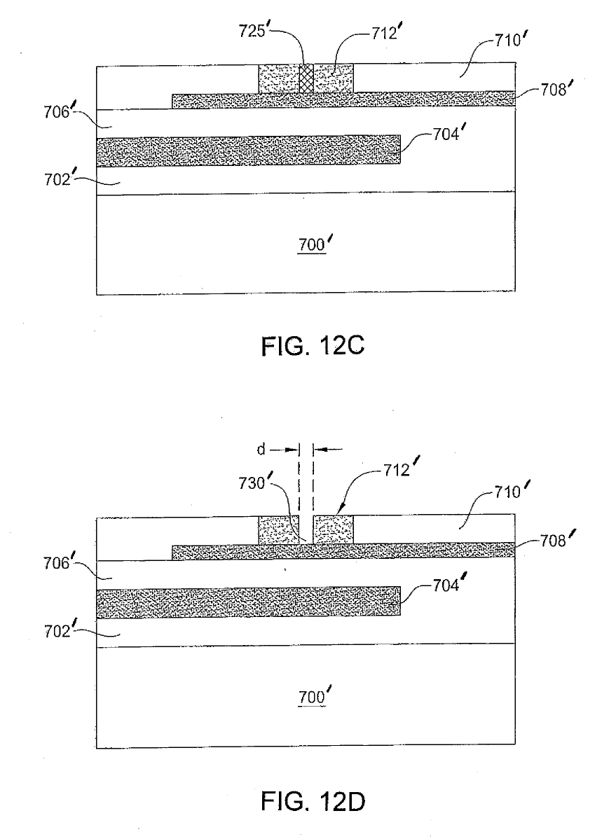

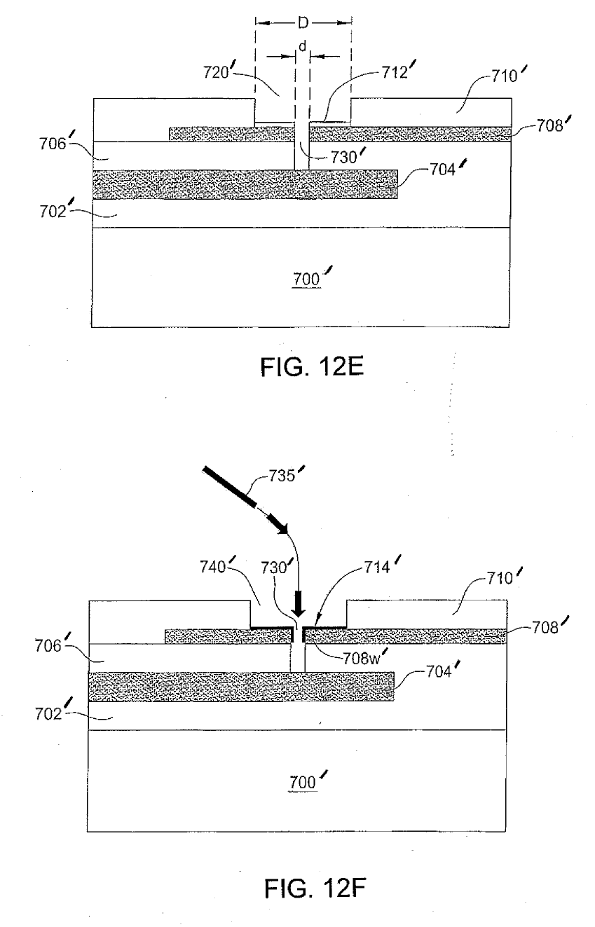

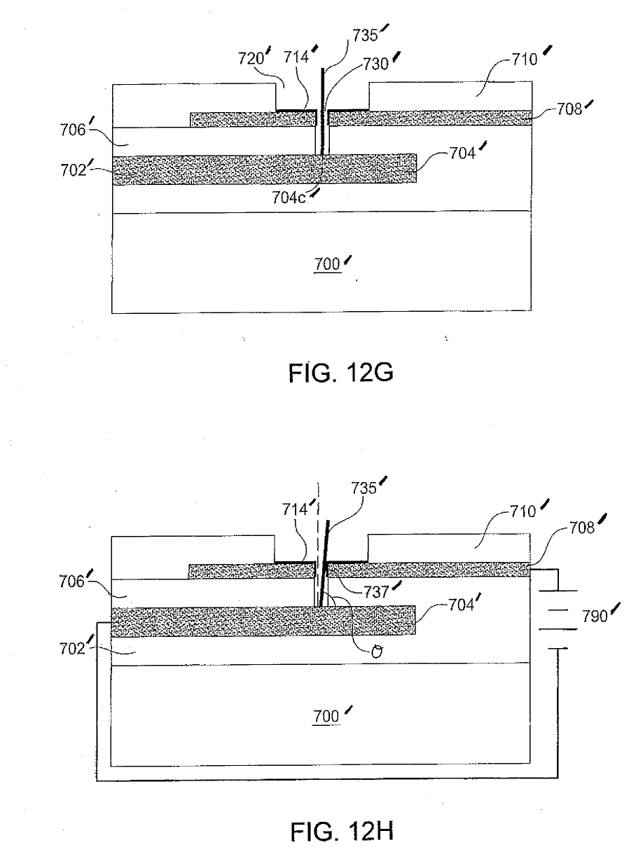

FIGS. 12A-I are schematic cross-sectional views illustrating various structures during a processing sequence for fabricating a vertical CNT-FET according to embodiments of the present invention. The term “vertical” is used to denote the transistor being formed so that the channel lies in a vertical orientation with respect to the plane of a substrate. One embodiment of the present invention provides for the CNT-FET being integrated with one or more CMOS devices, which are provided as “horizontal” devices with their channels in the plane of the substrate.

FIG. 12A shows a structure in which several material layers have been formed over a substrate and processed in previous steps (not shown) using techniques known to one skilled in the art of semiconductor processing. The process sequence to be described can be used to form one or more vertical CNT-FETs in a variety of semiconductor structures, including hybrid structures integrating CNT-FETs with CMOS devices at different stages of fabrication.

For example, in hybrid structures, the vertical CNT-FET (VFET) process steps are inserted into the process flow of the metal levels (i.e. interconnect levels) of the CMOS device. That is, the patterning for the VFET is done at the same time as one or more of the metal levels of the CMOS (at least three metal levels are needed for a VFET) and the VFET level device logic is incorporated into the interconnect levels along with the “horizontal transistor” interconnects. The VFETs becomes a part of the entire logic diagram along with the “horizontal transistor” logic.

FIG. 12A shows a structure that includes an insulating layer 702′ on a substrate 700′, which may generally be a silicon (Si) wafer, or the insulating layer may be the dielectric layer on which any of the appropriate metal levels is deposited in a CMOS integrated circuit and will depend on the circuit layout. Materials suitable for use as the insulating layer 702′ include silicon oxide (SiO₂), silicon nitride, among others.

A conductive layer 704′ is formed by depositing a suitable material, e.g., Al, Cu, TiN, or Co, over the insulating layer 702′ and patterned to form a source (or drain) of the vertical CNT-FET. The material for conductive layer 704′ should have sufficient adhesion to the CNT (to be formed as the channel and discussed in a later deposition step, e.g., FIG. 12F-G) during processing and minimal contact resistance with the CNT after the processing is completed. The sheet resistance of the material should also be sufficiently low to be compatible with low current operation, as are Al and Cu in standard CMOS integrated circuits. Alternatively, the contact between the CNT channel and the VFET source and drain may be provided as a composite material, which may include a metal known to have good adhesion and low contact resistance combined with another metal with a low sheet resistance. Combinations such as Co/Al, Co/Cu, Fe/Al, Fe/Cu may be suitable with Co or Fe in direct contact with the CNT. Most metals that are used as seed metals in chemical vapor deposition of CNTs may also be suitable to be in direct contact with EPD deposited CNTs.

Furthermore, if the CNT-FET is to be integrated with the first metal level of a CMOS device, then the substrate 700′ may correspond to the wafer and all of the process levels preceding the dielectric 1 level, while insulating layer 702′ and conductive layer 704′ may correspond to the dielectric 1 (D1) and metal 1 (M1) levels of the CMOS device, respectively. For example, the patterning of the conductive layer 704′ to form the source/drain of the CNT-FET is performed at the same mask level as M1 of the CMOS device.

After the conductive layer 704′ is patterned, an insulating material is deposited and the resulting structure is polished to form a planarized dielectric layer 706′. The thickness of the dielectric layer 706′, which corresponds to a separation between the source 740′ and the gate (to be formed) of the CNT-FET, is determined by the device specification. Dielectric layer 706′ may correspond to dielectric 2 (D2) level of the CMOS device in an integrated structure.

A conductive material is provided over the dielectric 706′ and patterned to form a conductive layer 708′, which, after further processing to be described below, will form a gate of the CNT-FET. In one embodiment, the material is aluminum (Al) having a thickness in a range from about 10 nm to about 100 nm depending on the requirements of the circuit design. Another suitable material includes copper, Cu. In the case of an integrated CNT-FET and CMOS process, in which the gate metal of the CNT-FET also acts as M2 in the CMOS metal stack, the material for the gate will also have to satisfy all of the current carrying specifications required by M2. Alternatively, the gate metal for the vertical CNT-FET may be provided as a separate metal level between two of the normal metal levels in the CMOS metal stack (i.e., requiring an additional metal level for each level of vertical CNT-FET).

A dielectric layer 710′ is formed by depositing an insulating material and patterning, e.g., with optical lithography, to define an aperture 720′, as shown in the structure of FIG. 12A. In one embodiment, the aperture 720′ has a diameter (D), or lateral dimension, of less than or equal to about 100 nm. The diameter D should be sufficiently large to accommodate a nanotube to be deposited onto conductive layer 708′. In one embodiment, the diameter D has a lower limit corresponding to the resolution limit of a lithography process used for defining the aperture 720′. For example, a resolution of about 90 nm can be obtained with conventional optical lithography at 193 nm. The dielectric layer 710′ may correspond to a dielectric 3 (D3) level of the CMOS device.

FIG. 12B shows a structure in which a multi-walled carbon nanotube (MWNT) 725′ is formed over the region of the conductive layer 708′ that is exposed or defined by aperture 720′. In one embodiment, MWNT 725′ has a diameter of between about 10 nm and about 40 nm. As will be shown below, MWNT 725′ is used to define another nanoscale via or aperture, which in turn will define a region for the deposition of a single-walled nanotube to serve as a channel of the FET.

According to embodiments of the present invention, the MWNT 725′ is deposited by electrophoresis, as previously discussed. For example, a suspension of MWNT nanotubes, e.g., pre-sorted, may be used. The parameters for electrophoresis and the configuration of aperture 720′ are selected such that only one MWNT 725′ is deposited inside aperture 720′. As previously mentioned, aperture 720 is sufficiently large to accommodate the diameter of the MWNT to be deposited within the aperture. Furthermore, the aperture 720′ is configured so that it will allow only a single MWNT to be deposited in the aperture. In general, the maximum diameter of 720′ depends on the diameter of the nanotube, the length of the nanotube, and the depth of the aperture. It can be estimated using finite element analysis for the specific geometry that is required by the circuit design. Furthermore, MWNT 725′ is substantially centered within aperture 720′ such that it is substantially vertically oriented, and its end is proximate a center 708C′ of the defined region on conductive layer 708′, e.g., within a few nanometers from the center 708C′. After deposition of the MWNT 725′, the wafer is rinsed in distilled and deionized water.

In a subsequent step, a dielectric material 712′ is deposited over the structure of FIG. 12B, preferably with sufficient thickness to at least substantially fill the aperture 720′ and above the top surface of the dielectric layer 710′. The structure with the dielectric material 712′ is then polished, e.g., by chemical mechanical polishing (CMP), down to the dielectric layer 710′. The resulting structure is shown in FIG. 12C, with the surfaces of the dielectric material 712′ and insulating layer 710′ being planarized. The remaining thickness of the dielectric layer 710′, which corresponds to the separation between the gate metal and the source/drain metal, is determined by the device specifications.

FIG. 12D shows a structure after the next process step, in which the MWNT 725′ is removed, either by oxidation or chemical etching, e.g., with an oxygen plasma, or with a process that is selective to the dielectric material 712′ and conductive material 708′. Thereafter, with the planarized layers 710′ and 712′ acting as a mask, conductive layer 708′ is etched down to stop at the insulating layer 706′. As shown in FIG. 12D, an aperture 730′, having a diameter or lateral dimension (d) corresponding to that of the MWNT 725′, is now formed in the conductive layer 708′, exposing the underlying insulating layer 706′.

FIG. 12E shows the next step, in which the dielectric material 712′ is partially removed by etching at least a top portion of the dielectric material 712′, thus effectively “restoring” the aperture 720′ previously formed in insulating layer 710′. Alternatively, dielectric material 712′ may also be completely removed to expose an underlying region of the conductive layer 708′ and the aperture 720′.

Aperture 730′ is extended through the insulating layer 706′ to stop at the conductive layer 704′. Preferably, the conductive layer 708′ acts as an etch mask for the etch of insulating layer 706′ using a reactive ion etch process. It is also preferable that the etches for 712′ and 706′ do not significantly etch insulating layer 710′. A region of the conductive layer 704′ is thus defined by the aperture 730′, with a lateral dimension d corresponding to the diameter of the MWNT 725′, e.g., in the range of approximately 10 nm to 40 nm. Aperture 720′, on the other hand, has a diameter D larger than aperture 730′, with aperture 730′ being substantially centered with respect to aperture 720′.

FIG. 12F illustrates a subsequent step of depositing a SWNT (to serve as a channel of the FET) and forming a gate dielectric. Various options are available at this stage for forming dielectric 714′ around the vertical sidewall 708W′ of conductive layer 708′, which will be the gate of the CNT-FET. One possible approach is to deposit the SWNT 735′ inside aperture 730′ prior to forming the gate dielectric. In one embodiment, the SWNT 735′ can be deposited using electrophoresis as previously discussed. An appropriate bias voltage from a DC source can be applied to the conductive layer 708′ via connections to electrical contacts at the edge of the substrate 700′. The electric field distribution arising from charge accumulation at the surface of insulating layer 710 will direct and focus the SWNT 735′ towards the center of aperture 720′, which also substantially coincides with the center of the aperture 730′. Thus, the electric field focusing allows SWNT 735′ to be automatically aligned within the much smaller aperture 730′, without the need for more elaborate alignment schemes. As shown in FIG. 12G, the deposited SWNT 735′ has one end contacting the conductive layer 704′ close to the center 704C′ of the region defined by aperture 730′.

A suitable dielectric material (e.g., silicon nitride of ˜2 nm to 30 nm) is then deposited to form a conformal dielectric layer 714′ over the conductive layer 708′ covering the sidewall 708W′ and the SWNT 735′, as shown in FIG. 12G.

Referring back to FIG. 12F, other variations to the sequence of forming the SWNT 735′ and gate dielectric 714′ may also be used, including for example depositing gate dielectric 714′ prior to deposition of SWNT 735′, using the native oxide on the conductor 708′ or by developing a plasma enhance chemical vapor deposition (PECVD) process to deposit an ultra-thin gate dielectric on conductive layer 708′ while using an electric field to keep conductive layer 704′ clear of gate dielectric during PECVD, and depositing SWNT 725′ by EPD after gate dielectric deposition.

After the deposition of SWNT 735′ and gate dielectric formation, the next step involves positioning or orienting SET 735′ so that it can contact the dielectric layer 714′ at the sidewall 708W′ of the conductive layer 708′. This can be done by applying a voltage across conductive layers 704′ and 708′, as shown in FIG. 12H. The DC voltage source 790′ may be an external source connected to both conductive layers 704′, 708′ through contact pads (not shown) at the edge of the wafer substrate 700′. The SWNT 735′ is pulled to one side, i.e., away from its perpendicular or vertical direction (indicated by a dashed line in FIG. 12H), thus forming an angle θ that is less than 90° with the top surface of the conductive layer 704′. The portion 737′ of SWNT 735′ that contacts the dielectric 714′ would correspond to the channel region of the CNT-FET. Minimizing the distance between the channel region and the sidewall 308W′ (the gate) is expected to provide improved performance in the CNT-FET.

Referring back to FIG. 12F, another variation involves making the aperture 730′ small enough, i.e., as defined by the deposited MWNT 725′ (see FIG. 12C-D), so that there is about sufficient space to accommodate the SWNT 735′ and the gate dielectric 714′. After depositing SWNT 735′, a suitable dielectric material is deposited to fill the remainder of the aperture 730′ region around the SWNT 735′, while using an electric field to keep conductive layer 704′ clear of gate dielectric during PECVD. This method would require that the MWNT 725′ be presorted in the EPD suspension to provide a narrow range of nanotube diameters for the step deposition shown in FIG. 7B.

In the next step (i.e., after SWNT deposition and gate dielectric formation), a sufficiently thick layer of dielectric material 716′ is deposited inside apertures 730′ and 720′ to surround the SWNT 735′ (see FIG. 12I), as well as to cover the insulating layer 710′. The material 716′ is then polished back to form a planarized surface with insulating layer 710′ and the other end of SWNT 735′. The remaining thickness of the dielectric layers 716′ and 710′, which corresponds to the separation between the gate metal and the source/drain metal, is determined by the device specifications.

A conductive material (e.g., Al, Cu, TiN, or Co) is deposited over the planarized structure and patterned to form a drain (or source) 718′ of the CNT-FET. The material for conductive layer 718′ should have minimal contact resistance with the CNT 735′ after the processing is completed. The sheet resistance of the material should also be sufficiently low to be compatible with low current operation, as are Al and Cu in standard CMOS integrated circuits. Alternatively, the contact between the CNT 735′ and the VFET drain may be provided as a composite material, which may include a metal known to have good adhesion and low contact resistance combined with another metal with a low sheet resistance. Combinations such as Co/Al, Co/Cu, Fe/Al, Fe/Cu may be suitable with Co or Fe in direct contact with the CNT 735′. Most metals that are used as seed metals in CVD of CNTs may also be suitable to be in direct contact with EPD deposited CNTs.

FIG. 12I shows the vertical CNT-FET, with its source region formed by conductive layer 704′, a channel provided by SWCNT 735′, a gate formed by the vertical sidewall 708W′ of conductive layer 708′, the gate dielectric 714′ at the gate region of 708W′, and the drain region formed by conductive layer 718′.

After completion of the vertical CNT-FET, electrical connections to conductive layers 704′, 708′ that are used for fabrication purpose, e.g., for electrophoresis, are severed using techniques known to one skilled in the art. Another level of vertical FET may be fabricated above the conductive layer 718′.

As shown above, embodiments of the present invention provide a method for controllable depositing nanotubes using electrophoresis in a defined region. The deposition region may be defined by an aperture, which can be configured to control the number of nanotubes that can be deposited in the region, as well as the spacings of deposited nanotubes. By properly configuring the aperture, e.g., providing a sufficiently small aperture size such as less than about 100 nm, one can also control the deposition such that only a single nanotube is deposited in the region, with lateral alignment precision of a few nanometers.

Embodiments of the invention also provide a room temperature process that is readily scalable and compatible with conventional fabrication processes and materials, and allow improved control over the properties of nanotubes being used in device fabrication. Furthermore, the process allows integration of nanotube field effect transistors with CMOS devices.

Although some examples have been discussed in the context of the deposition of carbon nanotubes, it is understood that the method can generally be adapted for deposition of other nanotubes. Furthermore, embodiments of the invention can generally be applied to depositing single-walled, multi-walled, semiconducting or metallic nanotubes for fabrication of different devices.

Turning to the field of nanotube sensors, the patch-clamp technique is a widely used method for investigating electrical activity in cells. In the patch clamp method, a micropipette is fabricated from a glass material and has an incorporated electrical contact. The micropipette is filled with a fluid that whose electrochemistry can be adjusted to mimic different extracellular conditions. The micropipette is attached to the cell membrane such that the local electrical activity of a small portion of membrane can be studied. The circuit is completed with an electrode that is in the liquid bath that surrounds the cell. The patch-clamp technique is used to measure ionic current through intramembrane proteins and to monitor the membrane potential as a function of external and internal stimuli.

It would be desirable to have an electrical probe that can measure electrical activity from within a live cell. Such a probe could be combined with nanomanipulation techniques to spatially resolve variations in cell electrochemistry that are involved in key cell processes. Since, in the majority of cases, there is a mechanical component in the chain of signals that carry out cell processes, it would also be desirable if the electrical probe can be made small enough to not distort the cell during insertion and measurement. This may also allow normal cell motility processes to proceed unencumbered by the probe. A carbon nanotube is a good candidate for such an intracellular probe because the diameter can be made as smaller than the width of the cell membrane (i.e. less than 3 nanometers). A difficulty of such a probe is that the entire shaft of the CNT is conducting, such that the portion of the CNT that is external to the cell will leave a conducting path to the bath electrode (if the patch-clamp circuit arrangement is used with the CNT probe). Embodiments of the present work relate to a method for fabricating a CNT probe that can be electrically connected to an external circuit and whose shaft in insulated up to the tip which is inserted into the cell.

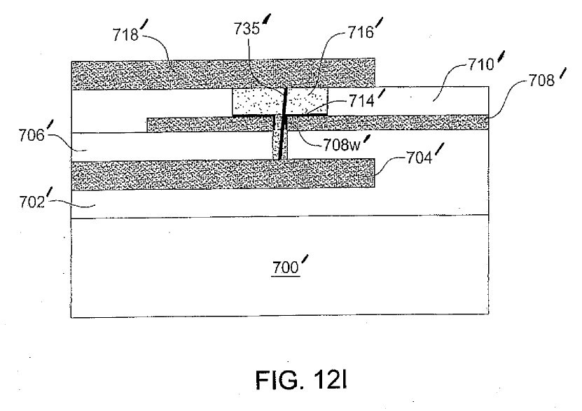

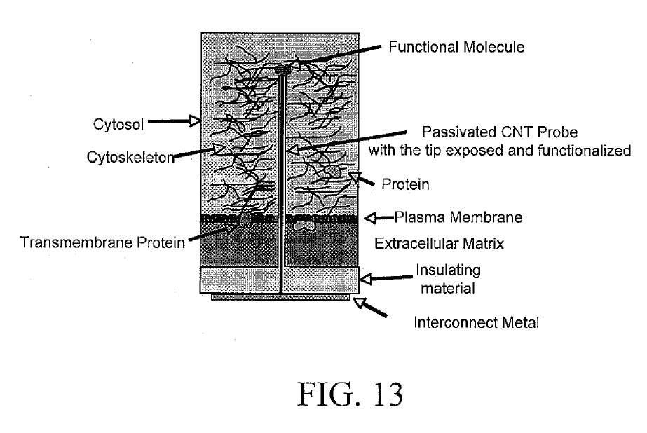

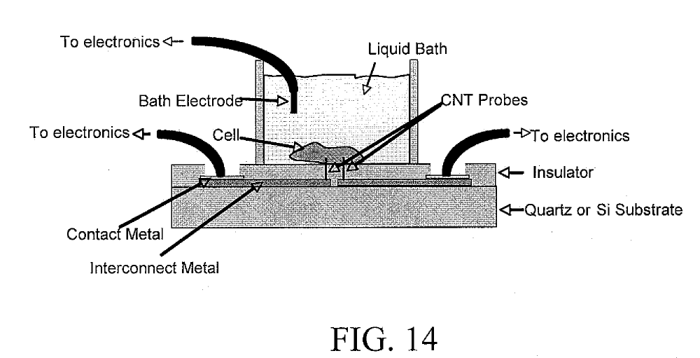

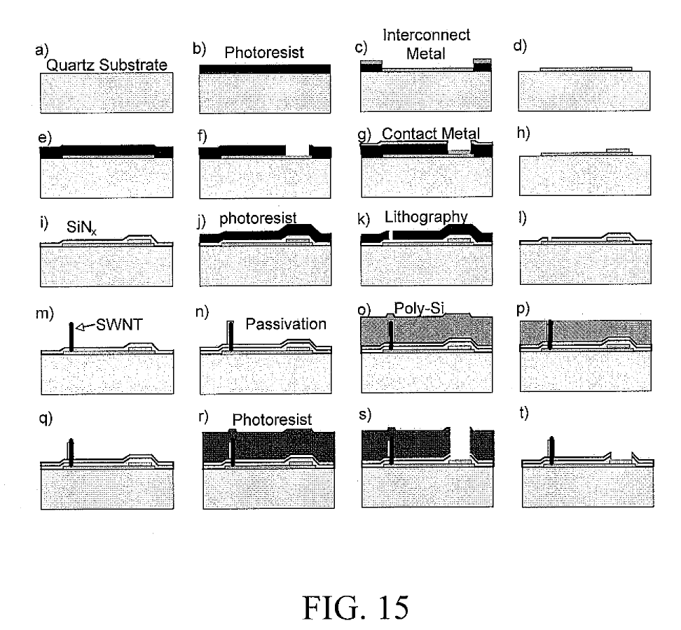

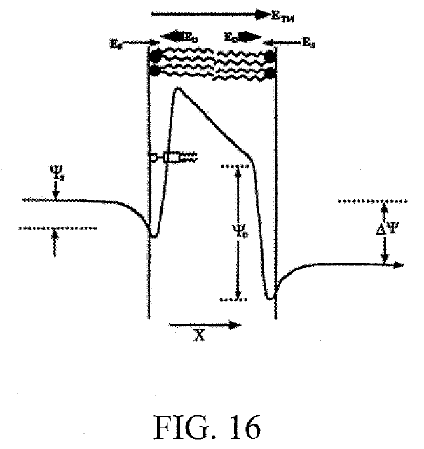

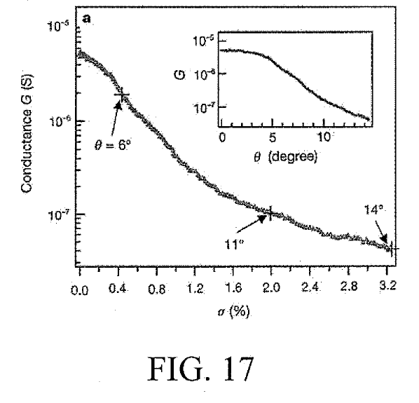

FIG. 13 shows a microscopic view of a CNT intracellular probe inserted in a cell. FIG. 14 shows an experimental arrangement for electrically probing a cell with one or more CNTs. FIG. 15 shows process steps for fabricating the CNT intracellular probe. FIG. 15 is a schematic of a process sequence for fabricating CNT probes, which includes the following process steps: a) quartz wafer substrate, b) photoresist deposition, c) pattern photoresist and deposit interconnect metal, d) remove photoresist, e) deposit photoresist, f) pattern photoresist, g) deposit contact metal (Au), h) remove resist, i) deposit insulating layer (silicon nitride), j) deposit photoresist, k) expose and develop photoresist and reactive ion etch silicon (RIE) nitride, l) remove photoresist, m) deposit CNT or SWNT using electrophoresis, n) deposit passivation layer (polymer or silicon nitride), o) deposit poly-Si, p) polish to desired probe length and RIE or chemically etch to uncover tips of CNT probes, q) poly-Si, r) deposit photoresist, s) expose and develop photoresist and RIE to open windows to contacts, and t) remove resist.

Thus, FIG. 15 shows quartz as the starting substrate, however, any suitable substrate will suffice including silicon. Quartz is advantageous for viewing the cell from below with an optical microscope (a standard practice in cell biology). Interconnect metal is deposited and patterned using photolithography and liftoff (FIGS. 15(a) thru 15(d)). The interconnect metal needs to be suitable for obtaining electrical contact and adhesion of CNTs. Interconnect metals may include (but not limited to) Co, Ni, or Fe since these are known to adhere to CNTs. The interconnect metal is provided as a contiguous or continuous layer such that it is electrically connected with contact pads that are at the edge of the wafer, since deposition of SWNTs will be by electrophoresis. There will also be contacts for individual device electrical connections. These contacts, which should be suitable for soldering or wire bonding (shown as Au contacts in FIG. 15) to external circuits, will be deposited and patterned using photolithography and liftoff (FIGS. 15(e) thru 15(h)).

In some cases, it will be advantageous to integrate the nanoprobe array into a circuit on the wafer (e.g. silicon) on which the array is deposited. In particular for the purpose of minimizing resistive and capacitive losses in the signal and to reduce noise, it would be advantageous to fabricate amplifier and multiplexing circuits on the same wafer as the nanoprobe array and to position each nanoprobe on an interconnect level that provides direct access to the input of the multiplexing circuit or amplifier input.

An insulating layer such as silicon nitride, SiNx, will then be deposited (FIG. 15(i)). The thickness of the insulating layer, SiNx, will be such as to provide an appropriate aspect ratio for electrostatic lens implementation after patterning. A 50 nm thick SiNx film is suitable for 100 nm windows in the next lithography step. The SiNx will be patterned using photolithography to form windows (also called vias) which can be on the order of 100 nm or less to form the geometry for an electrostatic lens during electrophoretic deposition of SWNTs (FIGS. 15(j) thru 15(l)). These windows may also be fabricated using electron-beam lithography or a focused ion beam milling technique. The lithography technique of the interconnect metal and vias will limit the separation between SWNT probes.

An electrophoresis technique will be used to deposit vertically aligned SWNTs selectively in the small windows (FIG. 15(m)). The SWNTs will be presorted for metallic SWNTs and filtered to limit bundles of SWNTs. The length of the CNTs or SWNTs will be less than about 1 micron and will be determined by the requirements for mechanical stability and penetration distance into the target cell. After SWNT deposition, a 2-5 nm conformal film of SiNx or suitable polymer (PTFE is possible) will be grown to encapsulate and passivate (insulate) the SWNTs (FIG. 15(n)). Since the length of the SWNT is difficult to control precisely during sorting and deposition, it is necessary to trim them afterwards. A poly-Si layer will be grown to support the entire structure (FIG. 15(o)). The surface will then be polished to give the desired SWNT length (FIG. 15(p)).

The tips of the CNT probes can then be uncovered by applying a brief RIE or chemical etch. This etch is to uncover the tips of the SWNTs. The length of SWNT that is left uncovered will depend on the etch rate and the time duration of the etch. RIE etches for SiNx are standard rates are well known and incorporated into commercial SiNx etching apparatus. The poly-Si layer will then be removed to leave free standing encapsulated SWTs (FIG. 15(q)). The final step is to remove the insulating layer on the contact pads. This can be done with standard photolithography and a dry etching process (see FIGS. 15(r) thru 15(t)).

### Single Wall Carbon Nanotubes for Membrane Potential and Intracellular Signaling Measurements

The SWNT probe array may be used to monitor the near-membrane intracellular signaling events (voltage, [Ca²⁺], enzymatic activity). It is a very promising device with a multitude of applications in physiology/biophysics, cell signaling, pharmacology, neuroscience and other fields that study various forms of the interface between extracellular and intracellular signaling.

Many cellular processes that are important for normal physiology, as well as therapeutically, occur in the vicinity of the plasma membrane. A large body of research is aimed at the coupling of electrical trans-membrane signals to intracellular events. These include such high-impact research areas as: excitation-contraction coupling, excitation-secretion coupling, and neuronal (post-synaptic) integration. The near-membrane domain is also critical in electrically quiescent tissues that are active communicators: lymphocytes, polar epithelia, endothelia, etc. Measurement of voltage between the tip of a single SWNT electrode and the extracellular space could be very useful, especially if it could be done with the nanometer spatial resolution. Previously, distribution of trans-membrane potential was simplistically inferred in theoretical applications assuming continuum electrostatics (constant field assumption^{i,ii} and mean-field approximation of Poisson-Nernst-Planckⁱⁱⁱ) or calculated from molecular dynamics of membranes and channels^{iv,v,vi,vii}. The trans-membrane distribution of the potential has been widely viewed to be that indicated in FIG. 4.^{viii} The difference in potential between the aqueous solutions on both sides of the cell membrane give rise to ΔΨ(˜100 mV) which is a function of the difference in ionic charge concentrations inside and outside of the cell. The dipole potential, Ψ_{D}, is thought to arise from dipoles just below the water/membrane interface and may be on the order of several hundred mV. Ψ_{D} affects the permeability of the membrane to hydrophobic ions and the binding of such ions to the membrane. The surface potential Ψ_{S}, arises from negatively charged lipids and may be several tens of mV. The distribution of potential (both trans-membrane and tangential) affects movements of voltage dependent and electrogenic transporters (channels, pumps, receptors, etc.). It also depends on their function. Simple recordings of voltage near functional channels have not been done before with sub-optical wavelength resolution and potentially could be of great interest to many. Transporters aside, the nanoprobe will permit direct measurements of charges on membrane surfaces. These have been shown to lower trans-membrane potential from the extracellular side by about 40 mV (averaged to all membrane surface). Extracellular Ca²⁺ and Mg²⁺ ions screen them at physiologically relevant concentration.^{ix} However, very little is known about surface charges on the intracellular side and about their tangential distribution. Our preliminary data on how intracellular Ca²⁺ affects movements of the voltage sensor in Ca²⁺ channels strongly indicate that negative charges on the intracellular side of plasma membrane exist and contribute to the interaction between Ca²⁺ ions and Ca²⁺ channels.^{x} A SWNT nano-electrode can be used to investigate how trans-membrane voltage changes at a spatial scale comparable to sizes of transporters and distances between them.

Functionalized SWNT probes specifically responsive to changes in chemical environment of the tip will be even more useful. Although the near-membrane intracellular space is a hot-spot where many intracellular signaling events originate and/or end, direct measurements there are limited to the micrometer scale of optical techniques. Even the most elegant single-molecule microscopy results involve significant statistical inferences due to the fundamental sub-micrometer optical resolution. A large spectrum of molecules (cyclic nucleotides CAMP and cGMP, IP3, diacylglycerol, etc.) have been extensively studied as second messengers of intracellular events initiated by activation of many types of hormone and neurotransmitter receptors. Various phospholipases, protein kinases and phosphotases (key enzymes whose activity initiates many signaling cascades) are targeted specifically to the plasma membrane. The importance of direct measurements of their activity and/or concentration of their substrates/products in the membrane domain are indicated in several research results.^{xi}

A unifying feature of most pathways interfacing extra- and intracellular events is the engagement of Ca²⁺ signaling. This is because most of Ca²⁺ ions are bound/sequestered inside cells, so that concentration of free Ca²⁺ is very low (˜100 nM) in the bulk of cytoplasm. On a “nano-scale” corresponding to protein sizes, this means that the probability to find one free Ca²⁺ in a (10 nm)³ volume is about 1%. In the 10-100 nm vicinity of open Ca²⁺ permeating channel (sources) or active pump (sinks), [Ca²⁺] rapidly changes in the range from 100 nM to 100 μM. Spatial and temporal distributions of near-membrane [Ca²⁺] are strongly influenced by gating/kinetic properties of Ca²⁺ transporters and by various buffers of different affinity and diffusional mobility. Although fluorescent Ca²⁺ probes with a wide assortment of properties are available to study intracellular Ca²⁺ signaling, understanding of the near-membrane Ca²⁺ dynamics, where the bulk of interactions between Ca²⁺ ions and other signaling events occur, is limited by the lack of direct measurements in the 100 nm domain under the plasma membrane. Ca²⁺ measurements in the space (˜100 nm) between plasma membrane and sarcoplasmic reticulum (cell organelle originating from endoplasmic reticulum and filled with Ca²⁺) of various types of cells would be just one, but good, example of the potential use of Ca²⁺-sensitive nano-electrode. Ca²⁺ dynamics in these junctions are key determinants of heart beat, blood pressure, muscle contraction, synaptic transmission, opto-electrical transmission in the eye and many other physiologically, as well as medicinally, important mechanisms.^{xii}

### Single Wall Carbon Nanotubes as Force Sensors

A CNT probe array may also be used as force sensors. It is known that single wall carbon nanotubes (SWNT) can undergo a two order of magnitude reduction in conductance under a 3% strain that is induced by bending.^{xiii} The measurements were done on an SWNT suspended over a trench and using an atomic force microscope (AFM) tip the bend the SWNT. A plot of the conductance versus strain is shown in FIG. 5. Simulations indicate that the major contribution to the reduction in conductance is highly localized around the bend and at large strains result from a change in atomic bonding configuration from sp² to sp³ along with a reduction in the π-electron density.

Using this conductance vs. bending behavior in a force sensor using SWNTs in the geometry shown in FIG. 13, one can calculate the force sensitivity. For a force F, the deflection of a cantilever of length L, diameter D, and elastic modulus E, satisfies the equation^{xiv}

$$F = \frac{3 π {ED}^{4}}{64 {L}^{2}} sin ( θ ) . \qquad Eq . ( 2 )$$

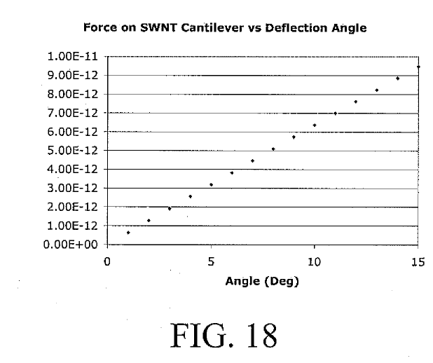

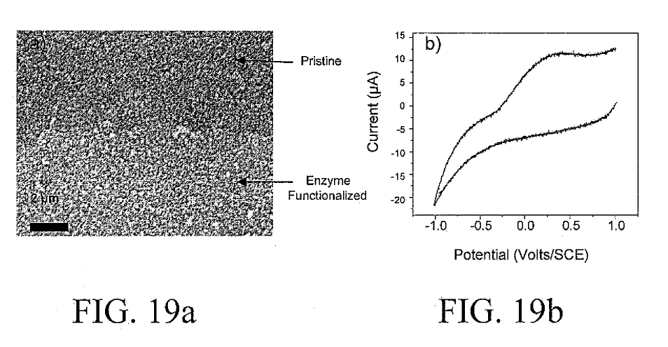

Equation 2 is a slight over estimate of the force since it assumes that the SWNT is solid. Using E=1.2 TPa, L=100 nm, and D=1.2 nm, F as a function of the deflection angle θ is plotted in FIG. 18 for the same bending range as reported by Tombler et al.¹³ It follows that a properly designed SWNT cantilever force sensor with this geometry should be sensitive to piconewton changes in force, which would make it an ideal candidate for probing biomolecular mechanics. Also, since the conductance change arises from a local deformation, the SWNT cantilever will be relatively insensitive to forces along its length but very sensitive to lateral forces (parallel to the substrate in FIG. 13).

The cell's cytoskeleton consists of a complex network of interconnected struts or tracks that function as structural elements (actin filaments, microtubules, and intermediate filaments) providing shape and form and as highways (actin filaments and microtubules) ridden by molecular motors to transport cargo and generate contractile forces. Unlike conventional architectural struts and highways, the cytoskeleton is a highly dynamic network whose organization and function is almost instantaneously changeable during normal physiological activity. Classic cellular examples of these dynamics are muscle contraction, flagellar motility, cell division, and amoeboid crawling. At the protein level these activities are driven by rapid assembly/disassembly of polymer and reorganization of polymer structure under the control of spatially and temporally binding partners that themselves are regulated by intracellular signaling pathways^{xv,xvi,xvii,xviii,xix,xx}. The assembled polymers are then used by the myosin protein family (for actin filaments) and the kinesin/dynein protein families (for microtubules) for force transduction via mechanochemical activity coupled to hydrolysis of ATP. Carbon nanotube-based methodologies can be used to explore dynamic mechanical properties of protein-protein interactions, which empower the cytoskeleton with its recognized diversity of structure and function. As the initial step in this development, carbon nanotube sensors will be used for probing the dynamic properties of actin filaments because this cytoskeletal system is easily manipulated for in vitro experimentation that will then be transferable to an in vivo setting.

Actin filaments are composed of actin monomers that freely assemble into polymer under physiological salt conditions with the only constraint being the monomer concentration must exceed the minimal critical concentration needed to nucleate assembly^{xviii,xx,xxi}. Once assembled the polymer can be modeled as a two-start helical filament consisting of two protofilament strands with right-handed pitch and a repeat spacing of approximately 14 monomers^{xxii,xxiii}. The repeat spacing exhibits some dispersion because of “angular disorder” in the spacing of monomers along the polymer^{xxiii}, which results from internal rotation/translational movement of monomer along the length of the filament^{xxiv}. The importance of such rotational dynamics lies not in the differences of helical pitch but in the resultant exposure of monomer interfaces created by changes in monomer orientation within the filament. The importance of such translational movements of monomer in the physiological activity properties of actin filaments was first noted in studies with the capping agent cytochalasin B^{xxv} and has subsequently been recapitulated for binding interactions with members of different actin binding protein families^{xxvi,xxvii,xxviii,xxix}.

The atomic structure identifies a globular protein with 4 domains separated by defined clefts that serve as natural bending points for translational movement within a polymer.^{xxx} Given the atomic structure of an actin monomer, any protein or agent that binds to an actin filament has the potential to either limit or enhance translational/vibrational movement of monomer which in turn changes the mechanical properties of the filament. Taking this one step further, changes in mechanical properties of a filament will ultimately dictate it physiological activity in vivo. Thus, any physiological or pharmacological agent that can alter the vibrational modes of an individual monomer within a filament would have the potential to alter the physiological properties of the filament. In one example, it has been shown that the actin binding protein cofilin reduces angular disorder along a filament, which in turn prevents binding of the pharmacological agent phalloidin.^{xxxi} Consequently, determining the dynamic properties of an individual actin monomer within an individual filament will provide fundamental information on how and possibly why particular combinations of actin binding proteins are used to build such diverse structures as stereocilia of hair cells in the cochlea, microvilli of the brush border in intestinal epithelial cells and the thin filaments of sarcomeres in striated muscle. While the aforementioned examples represent extremes of form and function, it is certainly reasonable to hypothesize that an individual cell must have domains of actin exhibiting different physical properties since different regions of the cell are known to exhibit cytoskeletal structures and functions.

At present, there is no real-time method to study the described dynamics with molecular resolution. The resolution of optical techniques using fluorescent analogs or fluorescent actin binding molecules is limited to a fraction of a micron even with sophisticated enhancement techniques and consequently these observations essentially provide bulk measurements from populations of monomers. Optical tweezers have been useful in measuring binding forces, but cannot track the dynamics of the actin monomers.

The present disclosure relates to SWNT-based methods to measure the activity of individual actin monomers and record the dynamics of the attachment of SWNTs to the cytoskeleton as a function of the physiological activity within living cells. The disclosed approach to methods development will build upon analysis of three different actin filament populations—individual filaments, magnesium-induced actin filament paracrystals, and bundles of actin filaments isolated from Limulus sperm^{xxxii,xxxiii}. Upon this base, it is possible to expand the application to examining effects of nucleotide, tension, and interactions with binding proteins/myosin on individual monomer dynamics. Importantly, the examination of effects on monomer dynamics that may be elicited by activities occurring microns away from the measurement site may be undertaken. The underlying physical basis of the measurement is that, as a monomer undergoes translational motions, there is an associated production of force, which will cause the SWNT to bend resulting in changes in SWNT conductance. An analysis of the magnitude and frequency of SWNT conductance changes can then be directly related to the forces and dynamics associated with individual monomer movements. Consequently, by using complementary techniques to induce changes in filament properties transformations, it may be possible to establish fingerprints for these dynamics, which in the future would be used to characterize the spatial and temporal dynamics of filament populations within cells.

### Functionalization of Single Wall Carbon Nanotubes

Functionalization of the SWNTs is a key enabler for the disclosed method. Functionalized carbon nanotubes offer enormous potential as components of nanoscale electronics and sensors. The prospect of these applications has led to successful functionalization of single wall (SWNT) and multiple wall carbon nanotubes (MWNT). These functionalizations may be separated into two categories: a non-covalent wrapping or adsorption and covalent tethering. In the first category, O'Connell et al. showed evidence for the formation of water-soluble SWNTs by wrapping with various polymers.^{xxxiv} Similarly, Zheng et al. have reported DNA wrapping onto SWNTs through relatively weak π-stacking.^{xxxv} On the other hand, several attempts have been made to achieve bonded functionalization of SWNTs in the second category. For example, fluorination of SWNTs^{xxxvi,xxxvii}, 1,3-dipolar addition^{xxxviii}, derivatization of small diameter SWNTs^{xxxix,xl}, glucosamine attachment^{xli}, and sidewall carboxylic acid functionalization of SWNTs^{xlii} have been shown to occur. As reported by these authors, a common outcome has been the increased solubility of SWNTs either in an organic solvent or water. Previous attempts at achieving enzyme linkage to SWNTs^{xliii} were done via non-covalent adsorption or via diimide activated amidation of SWNTs^{xliv,xlv}. Recently members of this research team reported the first study on functionalization of SWNTs with enzymes, achieved chemically by first acylation of SWNTs followed by amidation with the desired protein.^{xlvi} The two-step chemical method employs mild conditions and results in tethering of the organic or bioorganic functionality through a covalent bond. It is a simple, practical and highly effective protocol. This linkage of chiral molecules and enzymes to SWNTs has opened the possibilities for applications of carbon nanotubes in medicinal and biological fields, and in biosensor or chemically modulated nanoelectronic devices.

The nanotube sidewalls are rather inert and in some cases chemical bonding may become a complex task. To overcome such hurdle, a relatively facile and scaleable electrochemical strategy for the direct functionalization of SWNTs with nitro-groups has been developed.^{xlvii} This raises the possibility of wider use of electrochemical techniques for the controlled and in-situ functionalization of carbon nanotubes in device structures. The electrochemical functionalization of oriented SWNTs with 50 mg of enzyme β-NAD Synthetase was carried out in a three-electrode cell, with 0.1 M of KCl as the electrolyte and 80 ml of pH 7 phosphate buffer (40 mM).^{xlviii} The Si wafer with oriented SWNTs was directly used as working electrode, with a platinum wire as counter electrode and a saturated calomel electrode (SCE) as reference electrode. The enzyme attachment was verified with cyclic voltammetry. After reaction, the SWNT electrode was rinsed with reaction buffer and distilled water, and then dried in air. The SEM image after functionalization is shown in FIG. 7 along with the cyclic voltammogram. The dark region is pristine, while the lighter region is functionalized by the enzyme. In the proposed project we plan to functionalize the SWNTs with test enzymes and other molecules using an electrochemical process.

Measurements of Ca²⁺ will require an SWNT probe functionalized by adding to its tip compounds that strongly interact with Ca²⁺, e.g., bisulfite, or by adding other negatively charged molecules that will interact preferentially with strongly charged Ca²⁺ and/or Mg²⁺—the main intracellular divalent cations, rather than with K⁺ and Na⁺. Charged molecule attachment is best done electrochemically.

To investigate the dynamics of actin filaments, a “vehicle” must be attached to the tip of the SWNT that can subsequently bind to the actin filament when the SWNT is brought into close proximity. There are several possibilities for the type of vehicle and they include a chemical crosslinker, a pharmacological actin-binding factor, or an actin binding protein. Each have their advantages and disadvantages based on the type of question being asked, the required resolution of movement, the experimental set-up, etc. Initial experiments will make use of pharmacological agents such as phalloidin (a mushroom toxin), jasplakinolide (a marine sponge cyclic peptide), and dolastatins (isolated from sea hares). These are commercially available, bind actin filaments with high affinity, and have been chemically modified (fluorescently-labeled) to study actin. It is proposed that phalloidin/jasplakinolide will be attached to the SWNT probes to enable binding to the actin filaments for studying their dynamics. For phalloidin, two possible techniques may be employed for attachment in this application. One would use a fluorescent analog of phalloidin (eg. fluorescein-phalloidin) as an independent optical signal for actin binding by fluorescence energy transfer when using a rhodamine-labeled actin analog.^{xlix} Alternatively, there has been success with attaching Au to phalloidin which could then be used as a spatial marker for TEM investigations of actin.^{l} It is proposed that a similar technique be employed where Au is electrodeposited to the SWNT probe followed by attachment of phalloidin.

### REFERENCES

ⁱ D. E. Goldman, J. Gen. Physiol. 27, 37-60 (1943).
ⁱⁱ A. L. Hodgkin, B. Katz, J. Physiol. 108, 37-77 (1949).
ⁱⁱⁱ For a review see: B. Eisenberg, J. Comp. Electron. 2, 245-249 (2003).
^{iv} B. Roux, R. MacKinnon, Science 285, 100-102 (1999).
^{v} Y. Jiang, A. Lee, J. Chen, M. Cadene, B. T. Chait, R. MacKinnon, Nature 417, 523-526 (2002).
^{vi} G. Barreiro, C. R. W. Guimaraes, R. B. de Alencastro, Protein. Eng., 16, 209-215 (2003).
^{vii} T. Allen, O. S. Andersen, B. Roux, J. Gen. Physiol., 124, 679-690 (2004).
^{viii} E. Gross, R. S. Bedlack, Jr., and L. M. Loew, Biophysical Journal, 67, 208-216 (1994).
^{ix} For an overview see: Ion Channels of Excitable Membranes, 3rd Edition, ed. B. Hille, [Sinauer Associates, Sunderland, Mass.], 646-660 (2001).
^{x} D. Isaev, K. Solt, O. Gurtovaya, J. Reeves, and R. Shirokov, J. Gen. Physiol., 121, 555-571 (2004).
^{xi} Examples include: P. Huang, E. R. Lazarowski, R. Tarran, S. L. Milgram, R. C. Boucher, M. J. Stutts, PNAS 98, 14120-14125 (2001); M. Zaccolo, T. Pozzan, Science 295, 1711-1715 (2002); A. Demuro, I. Parker. Bio. Res., 37, 675-679 (2004); M. Miller, O. Safrina, I. Parker, M. D. Cahalan, J. Exp. Med. 200, 847-856 (2004); A. Demuro, I. Parker, Physiology News, 55, 24-26 (2005).
^{xii} E. Rios, M. D. Stern, Ann. Rev. Biophys. Biomolec. Struct. 26, 47-82 (1997).
^{xiii} T, W. Tombler, C. Zhou*, L. Alexseyev, J. Kong, H. Dai*, L. Liu, C. S. Jayanthi, M. Tang, S-Y. Wu, Nature, 405, 769-772 (2000).
^{xiv} J. M. Kinaret, T. Nord, and S. Viefers, Appl. Phys. Lett., 82, 1287-1289 (2003).
^{xv} J. M. Vasiliev, T. Omelchenko, I. M. Gelfand, H. H. Feder, and E. M. Bonder, Proc. Natl. Acad. Sci., 101, 12526-12530 (2004).
^{xvi} T. Omelchenko, J. M. Vasiliev, I. M. Gelfand, H. H. Feder, and F. M. Bonder, Proc. Natl. Acad. Sci. USA, 100, 10788-10793 (2003).
^{xvii} M. Krendel, E. M. Bonder, Cell Motil. Cytoskeleton. 43, 296-309 (1999).
^{xviii} E. M. Bonder, M. S. Mooseker, J. Cell Biol. 96, 1097-1107 (1983).
^{xix} M. Krendel, G. Sgourdas, E. M. Bonder, Cell Motil. Cytoskeleton. 40, 368-378 (1998).
^{xx} M. A. Wear, D. A. Schafer, J. A. Cooper, 10, R891-R895 (2000).
^{xxi} E. M. Bonder, D. J. Fishkind, M. S. Mooseker, Cell, 34, 491-501 (1983).
^{xxii} J. Hanson, Nature, 213, 353-356 (1967).
^{xxiii} E. H. Egelman, D. J. DeRosier, Biophys. J., 63, 1299-1305 (1992).
^{xxiv} D. D. Thomas, J. C. Seidel, J. Gergely, J. Mol. Biol. 132, 257-273 (1979).
^{xxv} E. M. Bonder, M. S. Mooseker, J. Cell Biol., 102, 282-288 (1986).
^{xxvi} A. McGough, B. Pope, W. Chiu, A. Weeds, J. Cell Biol. 138, 771-781 (1997).
^{xxvii} P. G. Allen, P. A. Janmey, J. Biol. Chem. 269, 32916-32923 (1994).
^{xviii} R. Censullo, H. C. Cheung, J. Mol. Biol. 243, 520-529 (1994).
^{xxix} D. J. Fishkind, M. S. Mooseker, E. M. Bonder, Cell Motil., 5, 311-322 (1985).
^{xxx} K. C. Holmes, D. Popp, W. Gebhard, and W. Kabsch, Nature., 347, 44-49 (1990).
^{xxxi} A. L. Moon, P. A. Janmey, K. A. Louie, D. Drubin, Mol. Biol. Cell, 6, 1423-1431 (1993).
^{xxxii} D. J. DeRosier, L. G. Tilney, E. M. Bonder, P. Frankel, J. Cell Biol., 93, 324-337 (1982).
^{xxxiii} L. G. Tilney, E. M. Bonder, D. J. DeRosier, J. Cell Biol., 90, 485-494 (1981).
^{xxxiv} M. J. O'Connell, P. Boul, L. M. Ericson, C. Huffman, Y. Wang, E. Haroz, C. Kuper, J. Tour, K. D. Ausman, R. E. Smalley, Chem. Phys. Lett., 342, 265 (2001).
^{xxxv} M. Zheng, A. Jagota, E. D. Semke, B. A. Diner, R. S. Mclean, S. R. Lustig, R. E. Richardson, N. G. Tassi, Nature Mater., 2, 338 (2003).
^{xxxvi} E. T. Michelson, I. W. Chiang, J. L. Zimmerman, P. J. Boul, J. Lozano, J. Liu, R. E. Smalley, R. H. Hauge, J. L. Margrave, J. Phys. Chem. B, 103, 4318 (1999).
^{xxxvii} J. Chen, A. M. Rao, S. Lyuksyutov, M. E. Itkis, M. A. Hamon, H. Hu, R. W. Cohn, P. C. Eklund, D. T. Colbert, R. E. Smalley, R. C. Haddon, J. Phys. Chem. B, 105, 2525 (2001).
^{xxxviii} V. Georgakilas, K. Kordatos, M. Prato, D. M. Guldi, M. Holzinger, A. Hirsch, J. Am. Chem. Soc., 124, 760 (2002).
^{xxxix} J. L. Bahr, J. Yang, D. V. Kosynkin, M. J. Bronikowski, R. E. Smalley, J. M. Tour, J. Am. Chem. Soc., 123, 6536 (2001).
^{xl} K. A. Williams, P. T. M. Veenhuizen, B. G. de la Torre, R. Eritja, C. Dekker, Nature, 420, 761 (2002).
^{xli} F. Pompeo, D. E. Resasco, Nano Lett., 2, 369 (2002).
^{xlii} H. Peng, L. B. Alemany, J. L. Margrave, V. N. Khabashesku, J. Am. Chem. Soc., 125, 15174 (2003).
^{xliii} B. R. Azamian, J. J. Davis, K. S. Coleman, C. B. Bagshaw, M. L. H. Green, J. Am. Chem. Soc., 124, 12664 (2002), A. Guiseppi-Elie, C. Lei, R. H. Baughman, Nanotechnology, 13, 559 (2002), S. G. Wang, Q. Zhang, R. Wang, S. F. Yoon, J. Ahn, D. J. Yang, J. Z. Tian, J. Q. Li, Q. Zhou, Electrochem. Commun., 5, 800 (2003), S. G. Wang, Q. Zhang, R. Wang, S. F. Yoon, Biochem. Biophys. Res. Commun., 311, 572 (2003).
^{xliv} X. Yu, D. Chattopadhyay, I. Galeska, F. Papadimitrakopoulos J. F. Rusling, Electrochem. Commun., 5, 408 (2003).
^{xlv} Y. Lin, F. Lu, Y. Tu, Z. Ren, Z. Nano Lett., 4, 191 (2004).
^{xlvi} Y. Wang, Z. Iqbal, S. V. Malhotra, Chem. Phys. Letters, 402, 96 (2005).
^{xlvii} Y. Wang, S. V. Malhotra, F. J. Owens, Z. Iqbal; Chem. Phys. Letters (2005) (accepted for publication).
^{xlviii} Y. Wang and Z. Iqbal, J. Materials—special issue on silicon nanoelectronics—submitted.
^{xlix} Y.-L. Wang, E. M. Bonder, M. S. Mooseker, D. L. Taylor, Cell Motil., 3, 151-165 (1983).
^{l} M. O. Steinmetz, D. Stoffler, S. A. Mueller, W. Jahn, B. Wolpensinger, K. N. Goldie, A. Engel, H. Faulstich, U. Aebil, J. Mol. Biol., 276, 1-6 (1998).

1. A method for depositing nanotubes in a region defined by an aperture, comprising:
a. configuring the aperture to permit at least one nanotubes to be deposited in a target region;
b. depositing at least one nanotubes through the configured aperture in the target region by electrophoretic deposition.

2. The method of claim 1, further comprising controlling the number of nanotubes deposited in the region.

3. The method of claim 1, further comprising controlling the pattern of the nanotubes deposited in the region.

4. The method of claim 1, further comprising controlling the spacing of the nanotubes deposited in the region.

5. The method of claim 1, further comprising pre-sorting of nanotubes to be deposited in the target region based on a predetermined criteria.

6. The method of claim 5, wherein the predetermined criteria includes nanotubes geometry.

7. The method of claim 1, wherein the target region is defined on a substrate that includes in insulating material layer, and wherein the aperture is configured in the insulating material layer.

8. The method of claim 1, wherein the aperture is configured by a lithographic process.

9. The method of claim 1, wherein the electrophoretic deposition of the at least one nanotubes is employed to define a nanotube vertical field effect transistor.

10. The method of claim 1, wherein the at least one nanotubes is functionalized.

11. The method of claim 10, wherein functionalization of the at least one nanotubes is undertaken by non-covalent wrapping, non-covalent adsorption or covalent tethering.

12. A method for fabricating a carbon nanotubes probe, comprising:
a. providing a quartz wafer substrate,
b. depositing and patterning a photoresist material on the quartz wafer substrate;
c. depositing an interconnect metal on the photoresist material,
d. depositing contact metal,
e. depositing insulating layer,
f. depositing at least one carbon nanotube using electrophoresis, and
g. depositing a passivation layer.
